(19) United States
(12) Patent Application Publication
(10) Pub. No.: US 2023/0114024 A1
(43) Pub. Date: Apr. 13, 2023

(54) HORIZONTAL TRANSISTOR STRUCTURE AND METHOD

(71) Applicant: Tokyo Electron Limited, Tokyo (JP)

(72) Inventors: Mark I. Gardner, Albany, NY (US); H. Jim Fulford, Albany, NY (US)

(73) Assignee: Tokyo Electron Limited, Tokyo (JP)

(21) Appl. No.: 17/581,493

(22) Filed: Jan. 21, 2022

Related U.S. Application Data
(60) Provisional application No. 63/253,753, filed on Oct. 8, 2021.

(51) Int. Cl. H01L 29/06; H01L 29/423; H01L 29/417; H01L 29/66; H01L 29/786; H01L 27/092; H01L 21/8238; H01L 29/40

(52) U.S. Cl. CPC H01L 29/0665; H01L 29/42392; H01L 29/41733; H01L 29/66742; H01L 29/78618; H01L 29/78696; H01L 27/092; H01L 21/823807; H01L 21/823814; H01L 21/823871; H01L 21/823878; H01L 29/401

(57) ABSTRACT

One or more 3D transistor structures that use one or more 2D materials as transistor channels along with methods for fabricating the same are disclosed. A 3D transistor can include a first carrier nanosheet at least partially surrounded by a first 2D material and a second carrier nanosheet at least partially surrounded by a second 2D material. The transistor can include a first source/drain structure in electrical contact with a first end of the first 2D material and a first end of the second 2D material. The transistor can include a second source/drain structure in electrical contact with a second end of the first 2D material and a second end of the second 2D material. The transistor can include a gate structure at least partially surrounding the first 2D material and the second 2D material.

### RELATED APPLICATIONS

This application claims priority to co-pending U.S. Provisional Patent Application Ser. No. 63/253,753 filed on Oct. 8, 2021, which is hereby incorporated by reference in its entirety.

### TECHNICAL FIELD

The present invention relates generally to the field of manufacturing semiconductor devices.

### BACKGROUND

Modern semiconductor integrated circuit device fabrication normally relies on well-established processes, such as film-forming depositions, etch mask creation, patterning, material etching and removal, and doping treatments, many of which are performed repeatedly to form desired circuits on a substrate. At the same time, the semiconductor industry has been facing a challenge in continuing to scale down and improve the performance of the integrated circuits in order to reduce their power consumption while increasing their rate of operation. In conventional fabrication, integrated circuits are usually manufactured in one plane, while wiring or metallization layers are typically be formed above the active device plane. Integrated circuits manufactured using these techniques are typically characterized as two-dimensional (2D) circuits. Although scaling efforts in the 2D circuit fabrication space had over the years improved the number of transistors per unit area, their continued improvement has recently stalled as individual transistor feature sizes have approached physical atomic limitations on the order of only single nanometers. Facing this challenge, device fabricators have expressed a desire for new solutions.

### SUMMARY

When semiconductor devices implemented with traditional wafer fabrication techniques include features having voltage potentials separated by barriers that are only a few atom sizes thick, various issues, such as leakage currents and short-channel effects, can emerge as some of the increasingly difficult challenges to overcome. Making transistor devices using traditional fabrication techniques at such small scales can be increasingly difficult as sizes continue scaling down.

The solution provided herein addresses this and other similar integrated circuit (“IC”) challenges by providing transistor architectures and methods of their fabrication that rely on 2D material layers applied to in-situ 3D horizontal nanosheet formations. Using this approach, transistor structures with effective 2D material channels can be formed, enabling existing IC fabrication facilities to continue scaling down transistors using existing fabrication tools and techniques. This makes a smooth and cost-effective acceptance of this technology by the IC fabrication industry more likely.

3D transistor structures can be fabricated using an in-situ approach in which one or more 2D material channels can be formed using 3D horizontal nanosheet formations implemented in a single material stack using techniques and fabrication steps described herein. One or more 3D transistors can be fabricated using a stack of materials that can include layers formed by any combination of mechanical exfoliation (ME), chemical vapor deposition (CVD), atomic layer deposition (ALD), and/or sputtering. An example structure can use a 2D material to provide a channel layer, although other materials, such as semiconductive behaving oxides, and other deposited films can be used in addition to or as an alternative to 2D materials. One or more carrier nanosheets can be used along with one or more 2D material layers, where the carrier nanosheet(s) may provide support for the 2D channels or otherwise enable the 2D channels to be positioned thereon so as to enable the 2D material layers to act as channel regions. The 2D material layers can be applied to one or more surfaces of the carrier nanosheet(s) and can partially or fully surround or envelop the carrier nanosheets to which the 2D material layers are applied.

On either end of the channel region (e.g., 2D material layers) a source and drain contacts (herein also referred to as the source and drain structures) can be provided using source/drain metal depositions. A gate structure can include a high-k gate dielectric material followed by a gate metal contact that can be applied on a least one side of one or more 2D material channels to form one or more 2D channels of a transistor. Alternatively, the gate structure can be applied on multiple sides, thus partially or fully surrounding or enveloping 2D material layers around the central portion of the carrier nanosheets spanned between the source and drain regions. In some implementations, the gate structure can surround the 2D material layers on all sides, forming a gate all around (GAA) structure for additional control and performance.

A dielectric isolation can be provided at distal ends of the channel region to isolate the source and drain contacts of the transistor from at least the conductive portion of the gate structure. Dielectric isolation and routing can be provided around the transistor structure to isolate the transistor structure from adjacent structures with the routing provided according to known techniques to electrically connect a transistor to a circuit. While some implementations described herein show only a single transistor or pair of transistors for the sake of simplicity, additional transistors could be formed above and beside the transistor structure(s) shown, such as may be desired for forming a 3D array of devices.

In some aspects, the present disclosure relates to a device. The device can include a source contact having a sidewall surface and a drain contact having a sidewall surface. The device can include a channel layer extending between the sidewall surfaces of the source and drain contacts. The channel layer can comprise a 2D material. A gate structure can be isolated from the source and drain contacts by an isolation dielectric. The gate structure can be provided on at least one side of the channel layer. The gate structure can comprising a gate contact and a gate dielectric between the gate contact and the 2D material. A portion of the gate dielectric can be positioned between the isolation dielectric and the 2D material.

The device can further include a carrier nanosheet on which the channel layer may be positioned. The device can also comprise the gate structure positioned on at least a second side of the channel layer. The device can include the 2D material formed between a top surface of the carrier nanosheet and the gate dielectric. The device can include the 2D material formed between a bottom surface of the carrier nanosheet and the gate dielectric.

The device can include the sidewall surface of the source contact and sidewall surface of the drain contact extending orthogonal to an underlying substrate. The device can include the carrier nanosheet formed to be oriented parallel with the substrate. The device can include the source contact electrically connected to a first end of the channel layer and the drain contact electrically connected to a second end of the channel layer. The device can include the source contact comprising a first electrically conductive material and the drain contact comprising a second electrically conductive material that is different than the first electrically conductive material.

In some aspects, the present disclosure relates to a method. The method can include fabrication steps for making a transistor structure that includes one or more 2D material channels made with an in-situ material stack. A patterned stack of layers can be formed. The patterned stack of layers can include a channel layer comprised of a 2D material. The patterned stack of layers can also include a gate structure provided on at least one side of the 2D material. The gate structure can comprise a gate contact and a gate dielectric between the gate contact and the 2D material. An isolation dielectric adjacent to the gate structure can be formed. Source and drain contacts on respective sides of the channel can be formed. The source and drain contacts can be isolated from the gate contact by the isolation dielectric and the channel layer can extend between the source and drain contacts.

In some aspects, the method can include forming the channel layer supported by a carrier nanosheet. The gate structure can be formed on at least a second side of the channel layer. The 2D material can be formed between a top surface of the carrier nanosheet and the gate dielectric. The 2D material can be formed between a bottom surface of the carrier nanosheet and the gate electric.

The method can also include forming the source contact and the drain contact that extend orthogonal to an underlying substrate. The carrier nanosheet may be formed to be oriented parallel with the substrate. The source contact may be formed to be electrically connected to a first end of the channel layer and the drain contact to be electrically connected to a second end of the channel layer. The method can also include forming the source contact with a first electrically conductive material and the drain contact with a second electrically conductive material that is different than the first electrically conductive material.

In some aspects, the present disclosure relates to a transistor. The transistor can include a transistor structure created in a patterned stack of materials. The transistor can include a first 2D material channel supported by a first carrier nanosheet extending between a source structure and a drain structure. The transistor can also include a second 2D material channel supported by a second carrier nanosheet extending between the source structure and the drain structure and above the first carrier nanosheet. The transistor can include a gate structure comprising a gate metal and a high-k gate material formed between the first 2D material channel and the gate metal and between the second 2D material channel and the gate metal.

The transistor can also include the gate metal at least partially surrounding the first 2D material channel that is in common with the gate metal at least partially surrounding the second 2D material channel.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1A, 1B, and 2-16 include cross-sectional and top down views of an example of a single 3D transistor structure fabricated using an in-situ approach in which one or more 2D material channels can be formed using 3D horizontal nanosheet formations implemented in a single material stack;

FIGS. 17-23 include cross-sectional views of an example of a multi 3D transistor structure fabricated using an in-situ approach in which 2D material channels can be formed using 3D horizontal nanosheet formations implemented in a single material stack;

FIGS. 24-38 include cross-sectional and top views of another example of a multi 3D transistor structure fabricated using an in-situ approach in which 2D material channels can be formed using 3D horizontal nanosheet formations implemented in a single material stack;

FIGS. 39-51 include cross-sectional views of another example of a multi 3D transistor structure fabricated using an in-situ approach in which 2D material channels can be formed using 3D horizontal nanosheet formations implemented in a single material stack; and

FIG. 52 is a flow diagram of an example method for fabricating 3D transistor structures using in-situ approach with 2D material channels using the process flows described in connection with FIGS. 1A, 1B, and 2-51, according to one or more embodiments.

### DETAILED DESCRIPTION

References will now be made to various illustrative embodiments depicted in the drawings, and specific language will be used to describe the same. It will nevertheless be understood that no limitation of the scope of the claims or this disclosure is thereby intended. Alterations and further modifications of the inventive features illustrated herein, and additional applications of the principles of the subject matter illustrated herein, which would be apparent to one of ordinary skill in the relevant art having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

It is understood that apparatuses, systems and devices produced by the structures described herein can be used or find their application in any number of electronic devices utilizing structures and/or circuits described herein, such as controllers, memory chips, systems or process on a chip processors, graphics processing units, central processing units and more. For example, structures and/or circuits described herein can include a part of systems utilizing memory, such as any computing systems including for example: computers, phones, servers, cloud computing devices, and any other device or system that utilizes integrated circuit devices.

The embodiments described herein may enable an increased stack height of one or more 3D semiconductor devices. Therefore, a semiconductor substrate can be used, but is not required, and any base layer material (e.g., glass, plastic, etc.) may be used instead of a traditional silicon substrate. A base layer, therefore, can be a semiconductor substrate, such as a silicon substrate. Some embodiments include 3D stacks of vertical conductive channel nanosheets in both CFET and side-by-side configurations.

The process flows described herein utilize 2D materials and/or semiconductive behaving oxide materials to form NMOS and PMOS devices. As such, the techniques described herein can be used to produce devices that are manufactured or “stacked” on any existing vertically stacked device or substrate, such as metal, dielectric, or otherwise, according to various implementations. The present techniques may improve upon other semiconductor manufacturing techniques by increasing the N height of stacked semiconductor devices, such as transistors, thereby providing high density logic. Although illustrations herein may show an NMOS device arranged over a PMOS device, alternative configurations may include a PMOS device over NMOS device, NMOS device over NMOS device, PMOS device over PMOS device, or other alternative including one or more NMOS devices or PMOS devices for any number of N stacks and in any order or arrangement.

Dielectric materials used herein can be any material or materials having low electrical conductivity, such as one millionth of a mho/cm. Dielectric materials can include, for example, silicon dioxide, silicon nitride, nanoporous silica, hydrogensilsesquioxanes (HSQ), Teflon-AF (Polytetrafuoethene or PTFE), and Silicon Oxyflouride. Dielectric materials can also include, for example, ceramics, glass, mica, organics, and oxides of various metals.

High-k dielectric, also referred to as high-k material, can refer to any material with a higher dielectric constant as compared to the silicon dioxide. For example, high-k dielectric can include hafnium silicate, zirconium silicate, hafnium dioxide, zirconium dioxide, and others.

Various metals, such as gate metal and the source/drain metal, can be used herein and can include any metal or any electrically conductive material. For example, metals used in the present solution can include aluminum, copper, titanium, tungsten, silver, gold or any other metal. For the purposes of the present solution, in addition to the metals, source/drain metals or gate metals can also include other electrically conductive materials, such as highly doped semiconductors, for example.

The present solution can also utilize 2D materials for forming transistor channels. 2D materials can include, for example, but are not limited to, WS2, WSe2, WTe2, MoS2, MoSe2, MoTe2, HfS2, ZrS2, and TiS2, GaSe, InSe, phosphorene, and other similar materials. These materials can be deposited by an atomic layer deposition (ALD) process and may be about 5-15 angstroms thick, the thinness lending to their name—2D material. 2D material layer can have a broader range of thicknesses, such as between 0.2 nm and 3 nm, for example. 2D materials may be annealed during or after the device formation process to recrystallize or grow the crystals and thereby improve electrical characteristics. 2D material, for example, can be electrically conductive.

Additionally or alternatively, channels may comprise one or more semiconductive-behaving oxide materials, which may be formed using certain elements that, when combined with oxygen, form a new material that exhibits semiconductive behavior. For example, the semiconductive behaving material can be “turned OFF” and can have a low or practically no off-state leakage current, and can be “turned ON” and become highly conductive when voltage is applied. Example materials to create an n-type channel, for example, may include, but are not limited to, In2O3, SnO2, In GaZnO, and ZnO. Example materials that can be used to create a p-type channel may be formed utilizing, for example, SnO. These materials may be further doped to improve the electrical characteristics. These materials may be referred to as conductive oxides or semiconductive behaving oxides for the purposes of this discussion. For the sake of simplicity, examples will primarily be focused on the use of 2D materials for the channel regions, but it should be understood that semiconductive behaving oxides may be used instead of, or in addition to, 2D materials.

As 2D materials can have a very large mobility, the 2D materials are herein described as one embodiment, however it is to be appreciated that other non-epaxially grown materials can be utilized. Since a 2D material can be precisely deposited on an insulative sheet, this can enable a very low Dt integration build of horizontal nanosheets with high performance. Advantageously, any base substrate material can be utilized as no epitaxial growth is required and the base substrate can be removed for further stacking of the devices.

Carrier nanosheets can be used to provide support for the 2D material layers. Carrier nanosheets can include dielectric materials or semiconductor materials on which 2D material layer, such as a monolayer of 2D material, can be deposited, grown or otherwise formed. Carrier nanosheet can include an electrically insulating material that can be used as a seed layer for the 2D material(s) used in the stack.

Reference will now be made to the figures, which for the convenience of visualizing the 3D semiconductor fabrication techniques described herein, illustrate a substrate undergoing a process flow in both top and cross-sectional views. Unless expressly indicated otherwise, each Figure represents one (or a set) of fabrication steps in a process flow for manufacturing the devices described herein. In the top and cross-sectional views of the Figures, connections between conductive layers or materials may be shown. However, it should be understood that these connections between various layers and masks are merely illustrative, and are intended to show a capability for providing such connections. They should not be considered limiting to the scope of the claims.

Likewise, although the Figures and aspects of the disclosure may show or describe devices herein as having a particular shape, it should be understood that such shapes are used as examples of the present solution and are merely illustrative and should not be considered limiting to the scope of the techniques described herein. For example, although most of the Figures show various layers in a rectangular shaped configuration, other shapes are also contemplated, and indeed the techniques described herein may be implemented in any shape or geometry. In addition, examples in which two transistors or devices are shown stacked on top of one another are shown for illustrative purposes only, and for the purposes of simplicity. Indeed, the techniques described herein may provide for one to any number N stacked devices. Likewise, the techniques described herein may provide for one to any number N nanosheets and 2D material layer channels stacked in a transistor. Further, although the devices fabricated using these techniques are shown as transistors, it should be understood that any type of electronic device may be manufactured using such techniques, including but not limited to transistors, variable resistors, resistors, and capacitors.

Despite the fact that illustrated embodiments for simplicity and brevity show examples of only a single or double transistor structures being formed using the techniques of the present solution, any number of transistors can be formed above and beside the transistor structures illustrated in examples illustrated, such as may be desired for forming a 3D array of devices. Likewise, even though illustrated examples show a transistor having usually two nanosheets and four 2D material channels formed thereon, it is understood that the transistors can be fabricated using any number of nanosheets and any number of 2D material channels.

Described herein is one or more structures and methods of fabricating 3D transistor structures that use one or more 2D material channels in an in-situ 3D horizontal nanosheet formation. The present solution describes structures and methods of fabricating one or more 3D transistors utilizing material channels, such as 2D material channels, which can be formed by mechanical exfoliation (ME), chemical vapor deposition (CVD), atomic layer deposition (ALD), and/or sputtering. The structure can be formed on an in-situ stack of layers of materials formed so as to position different parts or layers of the structure to complete portions of the transistor.

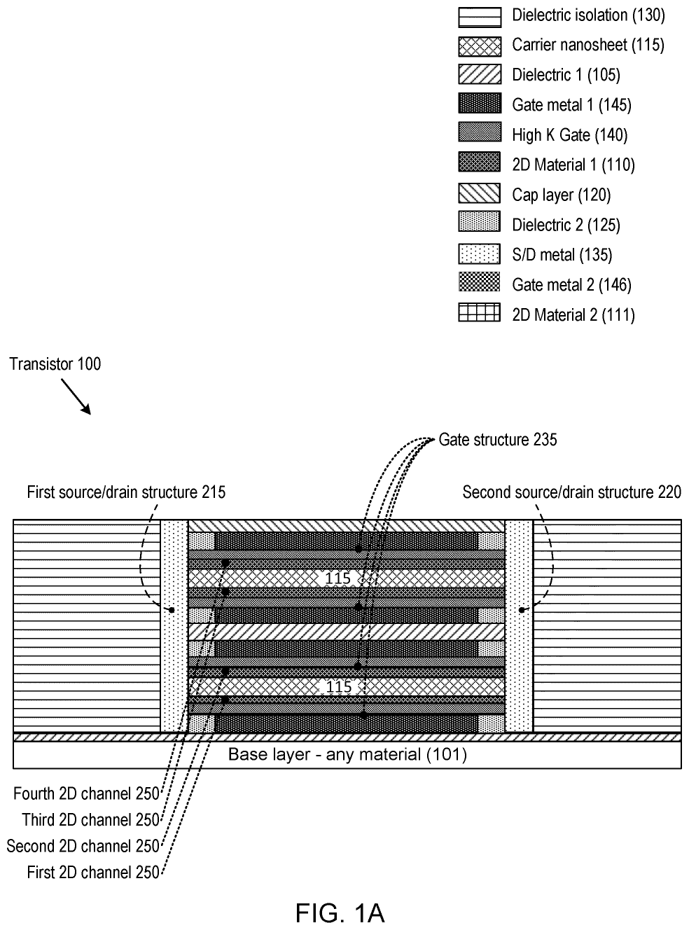

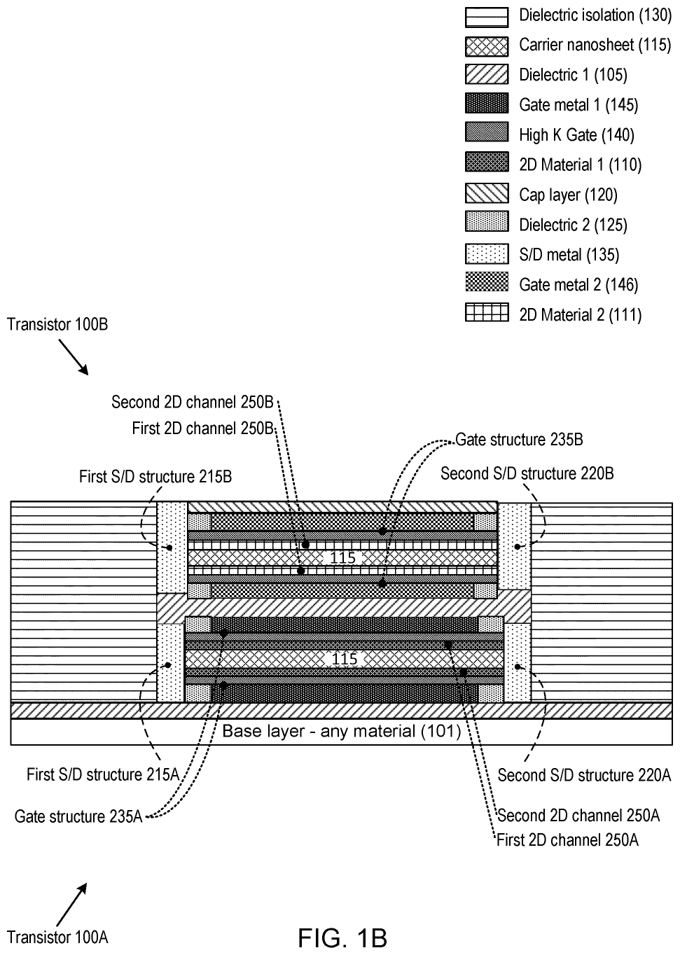

One example of the structure of a transistor 100 of the present solution is shown in FIG. 1A in which transistor 100 includes four 2D material 110 layers supported by two carrier nanosheets 115. In some implementations, other materials, such as semiconductive behaving oxides, and other deposited film can be utilized in addition, or as an alternative, to the 2D material 110 in order to form 2D channels 250, which can also be referred to as 2D material channels 250. Carrier nanosheets 115 can be partially, or entirely, surrounded by 2D material 110 layers, such as on one side, two sides, three sides, four sides or other number of sides of the carrier nanosheets 115. Each 2D material 110 layer, or a combination of material layers 110, when interfaced with, or surrounded by, the gate structure 235, can act as a 2D channel 250 of the transistor 100. The section of the transistor 100 in which 2D channels 250 are formed can be referred to as the transistor region.

In the example implementation shown in FIG. 1A, 2D channels 250 are formed on the bottom and top surfaces of the two carrier nanosheets 115, although it is understood that they can be formed on any number of carrier nanosheet 115 surfaces. Source and drain (“S/D”) contacts of the transistor 100, also referred to as the S/D structures 215 and 220, can be formed using S/D metal 135 and can be provided at the two opposing ends of the carrier nanosheets 115. A gate structure 235 can include a gate metal 145 contact and high-k gate 140 dielectric which can abut, interface with, or partially or fully surround the 2D material 110 layers to form 2D channels 250.

The gate structure 235 can entirely surround or envelop the central portion of each of the carrier nanosheets 115 that can be partially or fully surrounded or enveloped by 2D material 110 layers, thereby forming 2D channels 250 with a gate all around (GAA) structure. A dielectric isolation 125 can be provided at distal ends of the 2D channels 250 to isolate S/D metal layers 135 from the gate metal 145. A portion of the high-k gate 140 dielectric can be provided between the dielectric isolation 130 and the 2D material channel 250. Dielectric isolation 130 can be provided around the transistor 100 structure to isolate the transistor from adjacent structures and metal routing can be provided using known techniques to electrically connect the transistor 100 to a circuit or a device of which it can be a part. While some implementations described herein show only one or two transistors 100 for the sake of simplicity, additional transistors 100 could be formed above and beside the transistor structures shown.

Another example of the structure of the present solution is shown in FIG. 1B, in which two transistors, 100A and 100B can be fabricated. At the lower part of the structure, transistor 100A can be formed as an n-type transistor, while at the upper part of the structure transistor 100B can be formed as a p-type transistor. The entire structure comprising transistors 100A and 100B can include two different kinds of layers of the 2D material, including 2D material 110 layers for forming n-type transistor 2D channels 250A for the NMOS transistor 100A and 2D material 111 layers to form p-type transistor 2D channels 250B for a PMOS transistors 100B. Transistors 100A and 100B can also include different gate metals, including, for example, a gate metal 145 for transistor 100A and a gate metal 146 for transistor 100B. The gate metals 145 and 146 can include the same or different type of metal and can be electrically isolated from each other so that transistors 100A and 100B can be independently operated. Gate metals 145 and 146 and 2D materials 110 and 111 can each be formed, at least in part, as layers of materials in the material stack from which the transistor structure is formed.

In FIG. 1B, a transistor 100A can include 2D material 110 layers supported by a carrier nanosheet 115, the central portion of which can be partially or fully surrounded or enveloped by the gate structure 235A that comprises gate metal 145. The transistor 100B can include 2D material 111 layers supported by another carrier nanosheet 115, the central portion of which can also be partially or fully surrounded or enveloped by the gate structure 235B. The gate structures 235A and 235B can each include high-k gate dielectric 140, and same or different gate metals (e.g., 145 and/or 146). As gate structures 235A of transistor 100A and 235B of transistor 100B can be electrically insulated so as to be operated independently, the source and drain structures 215A and 220A of the transistor 100A can also be electrically insulated from the source and drain structures 215B and 220B of transistor 100B. While FIG. 1B shows only two transistor 100 structures, any number of NMOS and PMOS transistors 100 can be formed by using a single stack of material, by patterning or repeating the material stack layers on top of each other or beside each other as many times as necessary, in accordance with the figures and descriptions below. As would be appreciated by those skilled in the art, once various NMOS, PMOS or a combination of NMOS and PMOS transistors 100 are implemented, the transistors 100 can be interconnected to, or form any logic, memory, control or other circuit or device known used in the industry.

The structure and methods described herein can utilize the concept of an insulative dielectric as a base of non-epitaxially formed materials, such as 2D materials and semiconductive behaving oxides, also called conductive oxides. The processes described herein can utilize a starting stack materials that can include 2D materials 110 and 111, high-k gate 140 dielectric layers and metal gate 145 electrode materials, which can then be patterned as described in connection with Figures herein. Providing these layers of materials in a particular way as a starting stack can decrease the process steps that may be used to form the final structure (e.g., a transistor or a combination of transistors).

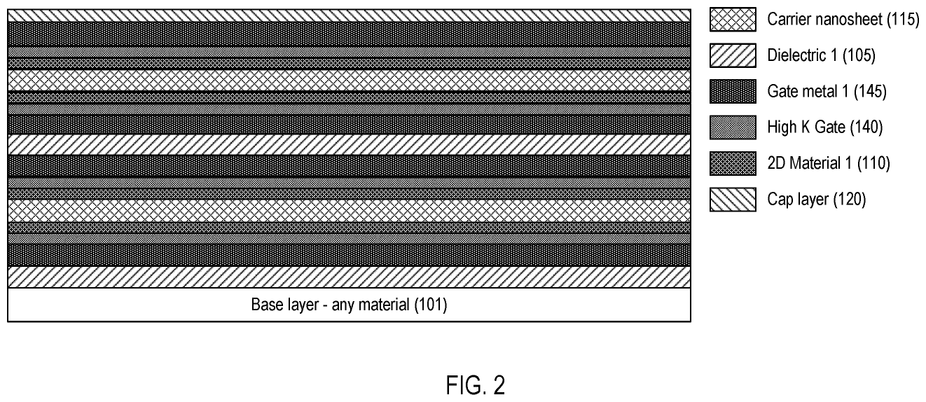

As shown for example in FIG. 2, a stack of layers of materials for fabricating a transistor 100 shown in FIG. 1A is illustrated. The stack of materials can include the materials for forming 2D channels 250 on a dielectric nanosheet (e.g., carrier nanosheet 115). In the example stack, some, most or all transistor 100 elements can be included in the initial stack, including for example, one or more carrier nanosheets, 2D material layers, high-k gate dielectrics and gate metals in any number of orientations.

As shown in FIG. 2, a layer stack can be created on a substrate 101. Substrate 101 can include any substrate known or used in the industry, such as a semiconductor substrate, including for instance a silicon wafer. However, as a semiconductor substrate is not required, any other substrate can be used instead, such as a glass, metal, ceramic, organic, or any other material substrate discussed herein. The stack of material formed on the substrate 101, can include several material layers of various thicknesses and types. The stack can include an order of layers, starting from the substrate, including: a first layer of dielectric 1 material, (in the legend shown as dielectric 105), followed by a first layer of gate metal 1 (in the legend shown as gate metal 145), followed by a layer of high-k gate material (in the legend shown as high-k gate 140), followed by a layer of 2D material 1 (in the legend shown as 2D material 110), followed by a carrier nanosheet (in the legend shown as 115), followed by a second layer of 2D material 110, followed by a second layer of high-k gate 140, followed by a second layer of gate metal 145 and followed by a second layer of dielectric 105. In the implementations or configurations in which a transistor 100 having only a single carrier nanosheet 115 and up to two 2D channels 250 is contemplated, the stack can end at this point with a cap layer 120, and the fabrication steps can be implemented as described in connection with the upcoming Figures.

However, as FIG. 2 illustrates a structure in which two carrier nanosheets 115 are used, and where four 2D channels 250 are contemplated, instead of adding the cap layer 120 on top of the second layer of dielectric 105, additional materials can be stacked thereon, including: a third layer of gate metal 145, followed by a third layer of high-k gate 140, followed by a third layer of 2D material 110, followed by a second carrier nanosheet 115, followed by a fourth layer of 2D material 110, followed by a fourth layer of high-k gate 140, followed by a fourth layer of gate metal 145, on top of which a cap layer 120 can be placed. While the example in FIG. 2 shows only 2D material 110 be used, it is understood that other 2D materials can be used instead, including, for example, 2D material 111 or any other discussed herein.

Additional layers of 2D materials 110 or 111, nanosheets 115, and gate high-k dielectric 140 and gate metal 145 could further be added on top to make an N tall stack of transistor 100 structures separated by an intervening dielectric layer 105. Likewise, any number of transistors or 2D channels 250 per transistor 100 can be contemplated and can be implemented by simply repeating the pattern as many times as needed.

One example implementation is described with regard to FIGS. 1-10 in which the number of transistor structures N=2, i.e., two transistors, are shown, each composed with a pair of 2D material layers provided around their own respective carrier nanosheets 115. The 2D material layers, such as 110 or 111, may be provided, thereby forming a 2D channel 250 (i) on only one side of a carrier nanosheet 115 (not shown), (ii) on two or more sides of the carrier nanosheet 115 (as shown in FIG. 1), or (iii) on all sides of the carrier nanosheet 115 (e.g., for an implementation of a GAA configuration). 2D material layers, including 110 or 111, can be provided as a standalone layer without a carrier nanosheet 115. For example, 2D material 110 or 111 layers, forming 2D channels 250, can be layered in between two layers of high-k gate 140 material. The material stack can be provided with a capping layer 120 that can include resist, dielectric or other suitable material. The 2D material 110 or 111 can be precisely deposited on an insulative carrier nanosheet to enable a very low Dt integration build of horizontal nanosheets 115 with high performance.

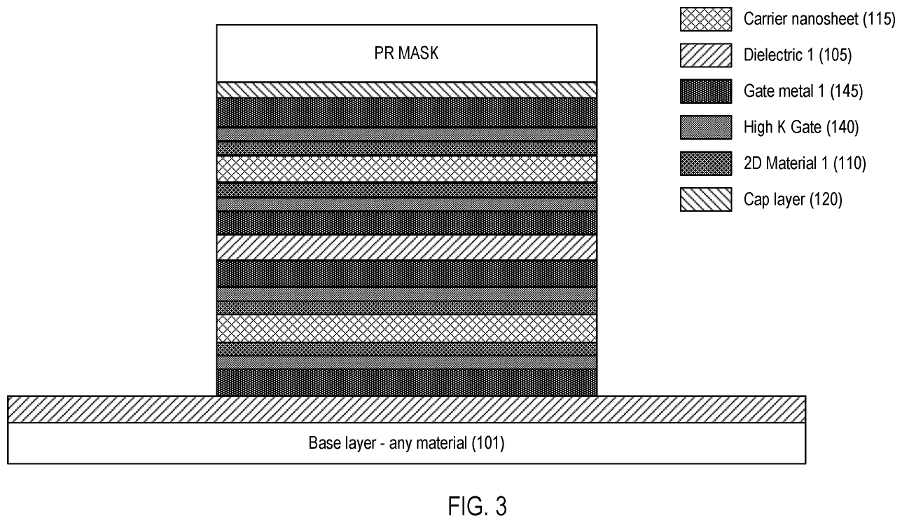

As shown in FIG. 3, the material layers can be masked using a photoresist (“PR”) mask or any other suitable material. Upon masking, the stack can be etched to a pattern that at least partially defines the stack portion in which the transistor channels will be formed along with etched areas in which S/D structures, such as 215 and 220, will be formed. The etching can be done down to the first dielectric 105 layer. In some implementations, the etching can also be done to the base layer 101 (e.g., the substrate). The PR mask can then be removed.

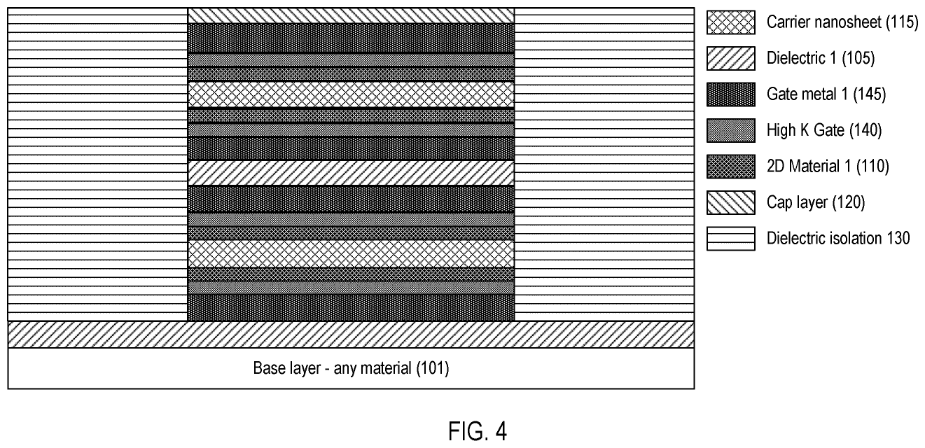

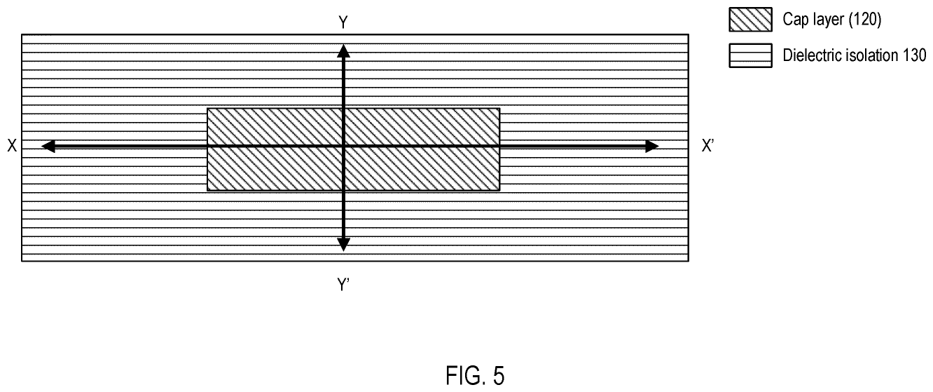

As shown in FIG. 4, dielectric isolation can be formed around the transistor structures using dielectric isolation 130 material. This can be done for example using material deposition or epitaxial growth, although other methodologies can be used. Upon application of dielectric isolation 130, a chemical mechanical planarization (“CMP”) or polishing can be used to align the upper surface of the dielectric isolation 130 with the cap layer 120 of the structure. FIG. 5 shows the top view of the general structure outline as defined by the capping layer 120, after the fabrication steps in connection with FIG. 4 are completed.

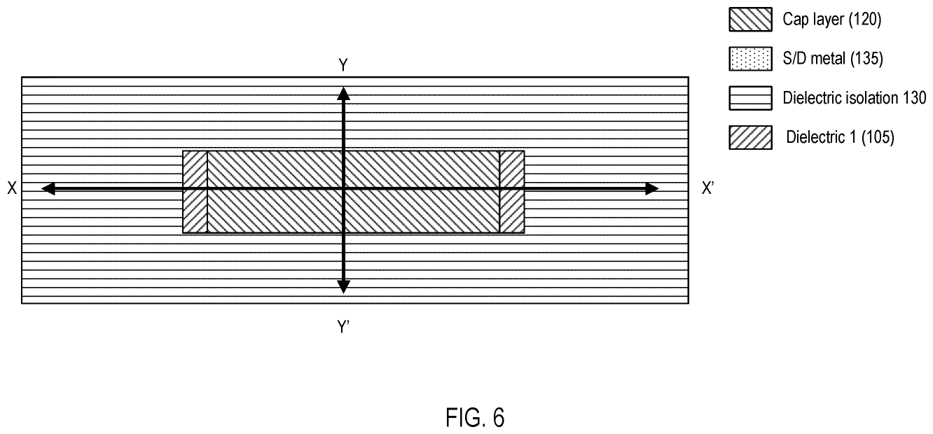

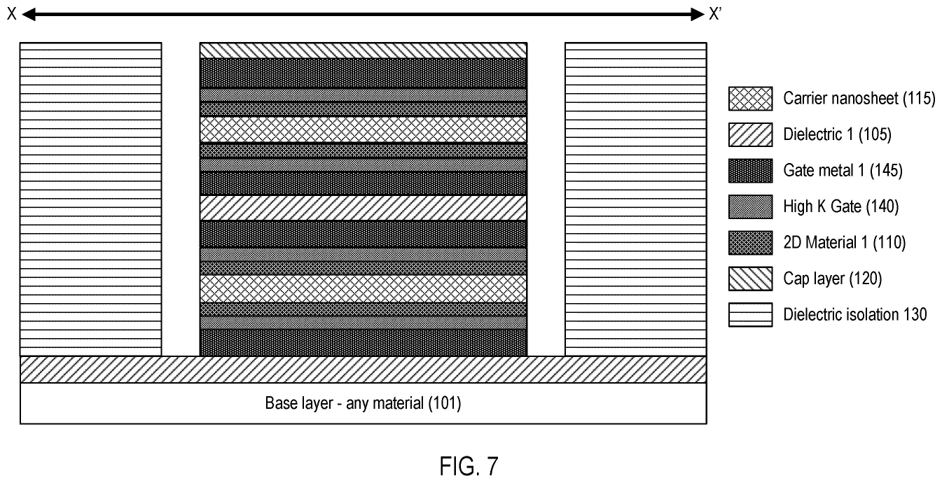

As shown in FIG. 6, openings can be formed by masking (not shown) and etching downward to form S/D contact regions in which S/D structures 215 and 220 are to be formed. The etching can be done to the substrate 101 level or to the dielectric 105 layer. FIG. 7 shows a side view of the openings at this stage or step in the process. Either before or after the mask removal, 2D material 110 can be selectively formed on the exposed sidewall portions of the carrier nanosheet 115 between the 2D material 110 pair of layers (this sidewall 2D material layer is not shown). In some cases this can encircle, enclose, envelop or further cover the exposed nanosheet with 2D material 110. For example, this can result in the nanosheet 115 being covered by 2D material 110 on carrier nanosheet 115 bottom surface, top surface and the two side surfaces at the distal end of the structure that were etched out. By adding 2D material 110 at the sides of the carrier nanosheet 115, a larger contact area between the 2D material 110 and to-be-deposited S/D metal structures 215 and 220 can be formed.

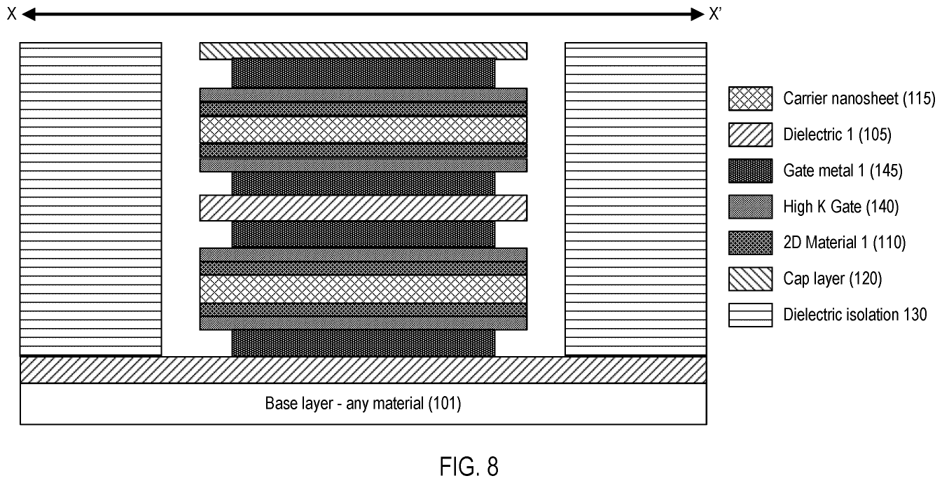

As shown in FIG. 8, a portion of the gate metal 145 layers can be indent etched from the side to form indented surfaces of the gate metal 145 layers with respect to the 2D material 110 layer and/or the high-K gate 140 dielectric layer. By indenting the gate metal 145 layer, a space for electric insulation between gate metal 145 and S/D metal 135 can be formed. S/D metal 135 can be used in the later or other fabrication steps to form S/D structures or contacts 215 and 220.

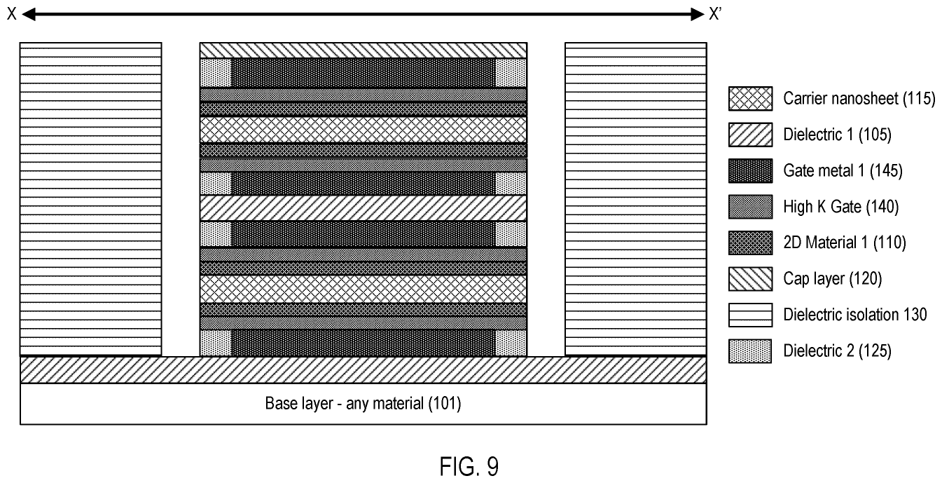

As shown in FIG. 9, dielectric 2 (in the legend shown as dielectric 125) can be deposited to fill the recessed areas left by indent etching of the gate metal 145. This deposition of dielectric 125 can be done by depositing the dielectric 125 into the etched areas, filling them out entirely and then etching back the downward directional trench, thereby leaving the dielectric 125 in the areas next to the gate metal 145 that were indent etched earlier. Additionally, dielectric 125 provides isolation of gate metal 145 layers from the to-be-formed S/D metal 135 regions.

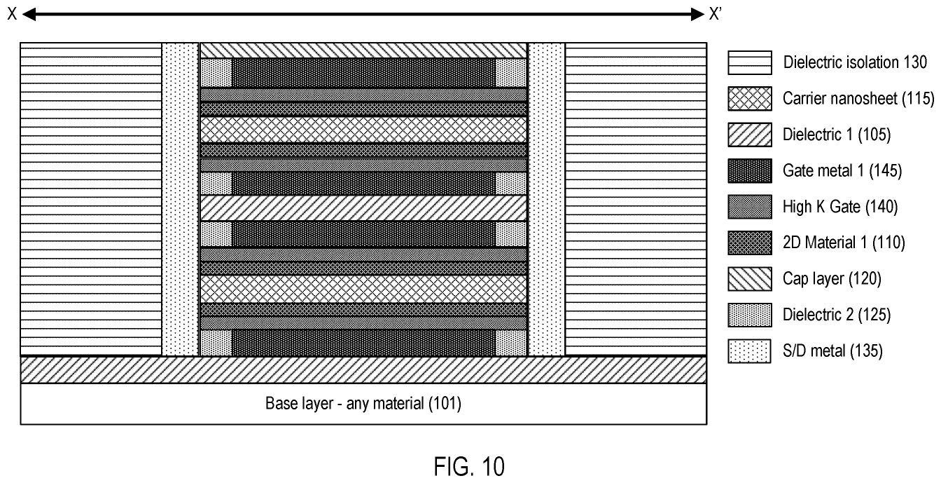

As shown in FIG. 10, Source and drain structures 215 and 220 can be formed by depositing S/D metal 135 in the exposed trenches. As dielectric 125 can remain in the recessed indent etched areas of the gate metal 145, S/D metal 135 can be deposited so as to be electrically insulated from the gate metal 145.

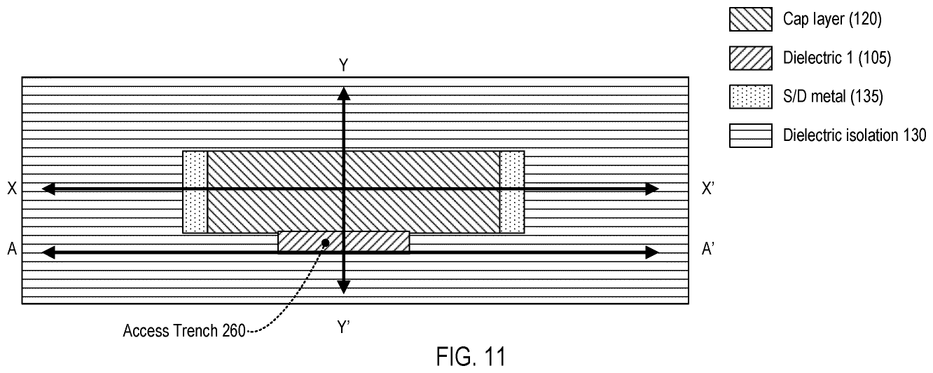

As shown in FIG. 11, a portion of dielectric isolation 130 can be masked (not shown) and etched directionally downward so as to expose a central portion of the layer stack (e.g., around the channel region). Typically, this involves forming an access trench 260 on one or both of the sides of the channel region, (e.g., other than the distal ends of the structure wherein S/D structures 215 and 220 are to be formed). The structure can include, and the fabrication steps can implement, one or more access trenches 260, which can be wider or narrower and may extend laterally along the length of the transistor (e.g., the X axis) anywhere from one interface between the gate metal 145 and dielectric 125 to the other interface between the gate metal 145 and dielectric 125. In some implementations, access trench 260 can extend from a first S/D structure 215 to the second S/D structure 220. Access trench 260 can extend along the entire length of the 2D channels 250 and can be on either side of the structure or on both sides of the structure. When two access trenches 260 that extend along the entire length of the 2D channels 250 are used, a GAA structure 235 can be implemented enclosing or surrounding the entire length of the 2D channels 250. It is understood that access trenches 260 can be shorter than the 2D channels 250 and can be centered at the midpoint of the 2D channels 250 and cover any portion of the channel region, such as up to 10%, 20%, 30%, 40%, 50%, 60%, 70%, 80%, 90% or 100% of the channel region.

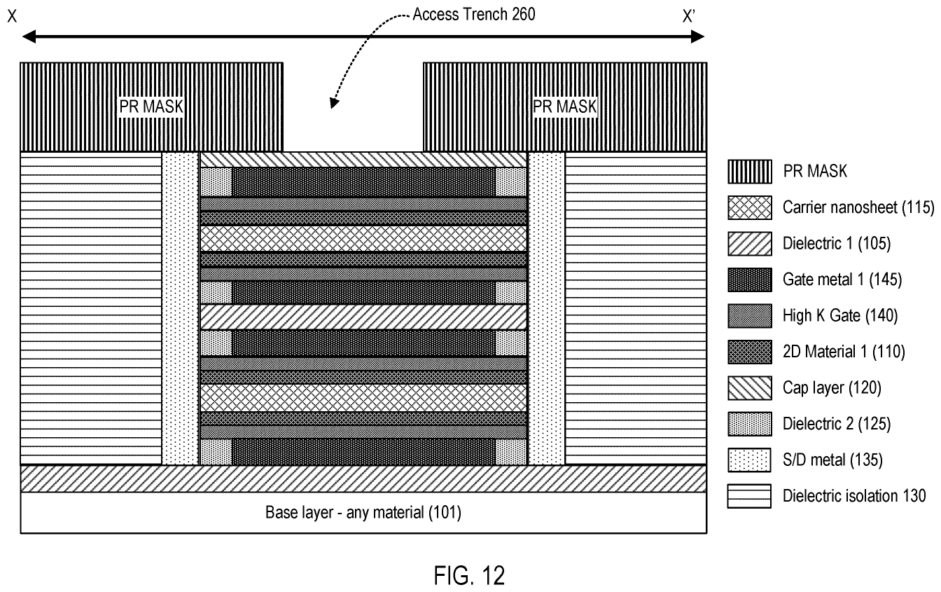

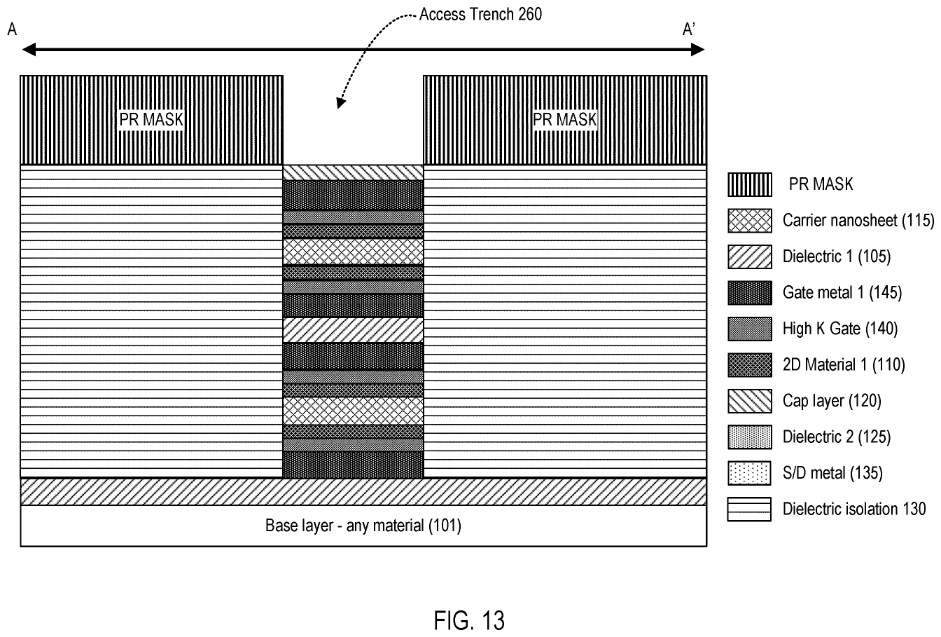

FIG. 12 shows a profile view of the stack along line X-X′ of FIG. 11. FIG. 13 shows a profile view of the stack through the side profile of the access trench 260, i.e., along line A-A′ of FIG. 11. The access trench 260 in FIG. 13 shows the trench exposing the entire stack of material exposed along the line A-A′. The PR mask shown in FIGS. 11-13, can allow for opening up the gate metal 145 region such that all gate metal 145 electrodes (e.g., from all gate metal 145 layers in the stack) can be tied together for one device along A-A′ line prior to etch, thus one side of the nanosheet 115 stack is opened up for future metal connection along A-A′ stack.

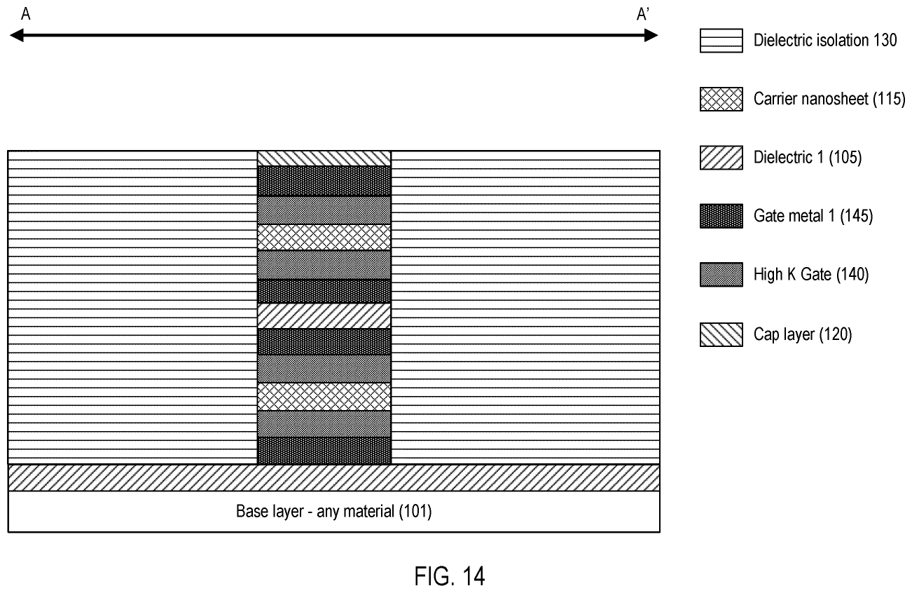

As shown in FIG. 14, PR mask can be removed and a high-k 140 material can be selectively deposited in the access trench(es) 260 on exposed portions of the 2D material 110 and/or sidewall surfaces of the carrier nanosheet 115 (e.g., for GAA) to form a gate high-k 140 dielectric layer. By depositing high-k gate 140 over the exposed 2D material 110, electrical isolation is made between the 2D material 110 and the gate metal 145 to be deposited next to form the gate structure 235. Prior to the deposition of the high k material 140, an additional 2D material maybe formed connecting the channel layers around the carrier nanosheet 115. Selective formation of the additional 2D material on the exposed 2D material 110/111 and the carrier nanosheet 115 and without forming on other surfaces allows formation without additional masking.

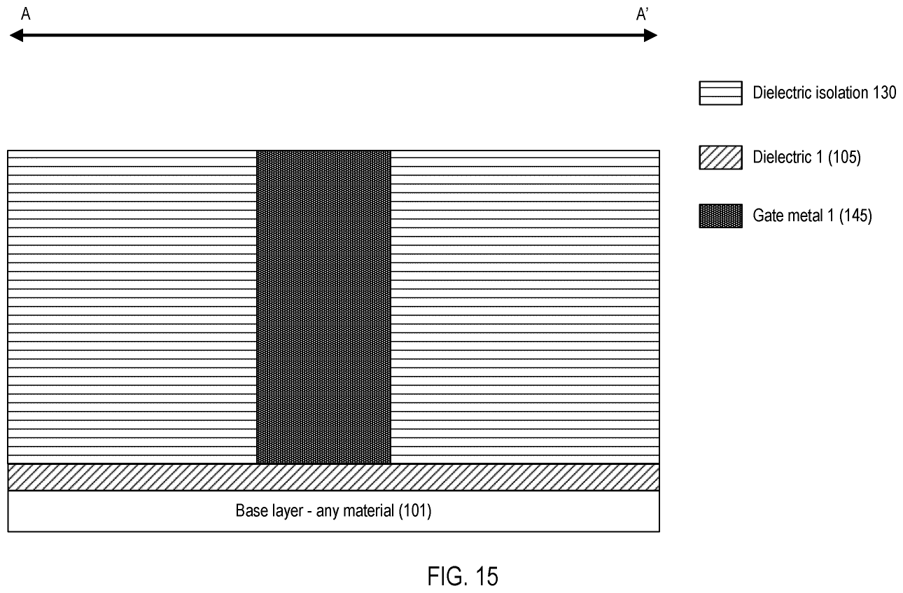

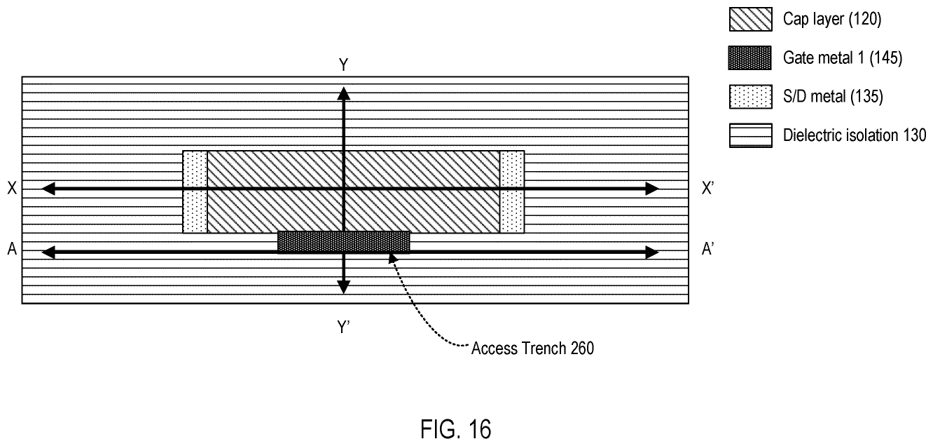

As shown in FIGS. 15 and 16, a gate metal 145 can be formed in the access trench(es) 260 covering exposed gate high-k 140 dielectric to complete the transistor 100 structure. Because gate high-k 140 is disposed between 2D material 110 and gate metal 145, all gate electrodes (e.g., gate metal 145 layers) can be connected, but electrical isolation of 2D material 110 is preserved. The resulting transistor can include four 2D channels 250, two for each carrier nanosheet 115 (e.g., one on each bottom and top surface of the carrier nanosheet 115) thus providing a quadruple drive strength for the transistor.

It is understood that the same structure can be used for less than four 2D channels 250. In the implementations in which only two 2D material 110 layers are used, only up to two 2D channels 250 can be implemented. Likewise, if 2D material 110 layers are implemented on the sidewalls of the carrier nanosheets 115 (e.g., the areas formed between the length and the thickness of the carrier nanosheets 115) then for a single cuboid shaped carrier nanosheet 115 four 2D channels 250 can be formed (e.g., on the bottom surface, top surface and the two side surfaces). Routing (not shown) can then be provided according to conventional techniques to connect the source, gate and drain to a circuit. The resulting structure of the fabrication steps and techniques described from FIGS. 2-16 can be shown, for example, in FIG. 1A.

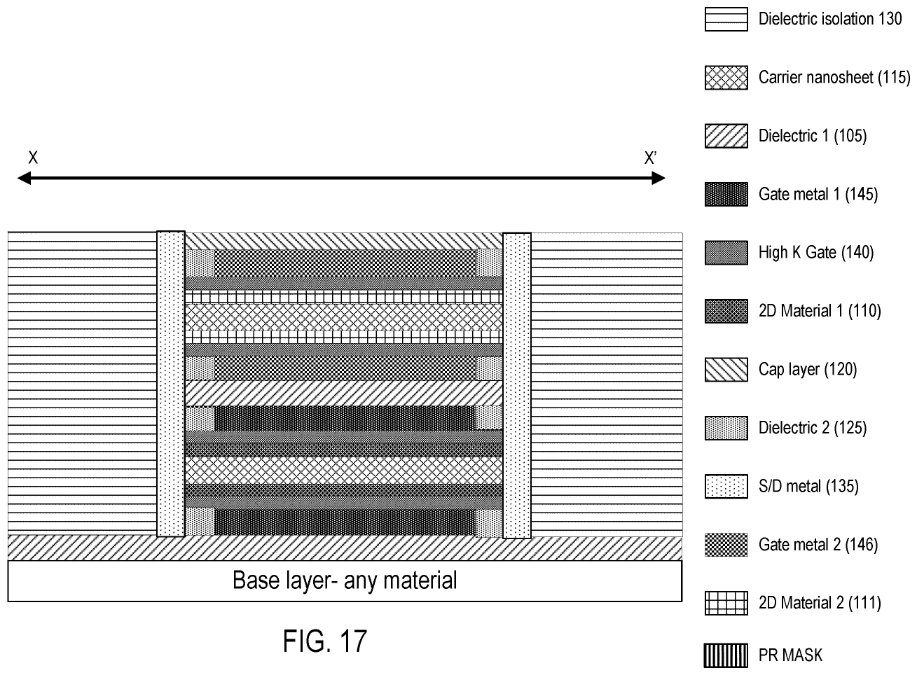

To complete the structure that is illustrated in FIG. 1B (e.g., the structure utilizing two different kinds of 2D materials and two different kind of gate metals), similar fabrication steps and techniques to those described in connection with FIGS. 3-16 can be used, except that the starting material stack can be different than the one shown in FIG. 2 and additional fabrication steps, such as those described in FIGS. 17-23, can be completed. Therefore, the structure from FIG. 1B can be completed with a material stack that includes two unique 2D materials and gate metals, followed by steps in FIGS. 17-23.

Referring back to the material stack of the structure in FIG. 1B, shown in FIG. 17, the material stack can be changed from the one described in connection with FIG. 2. For example, instead all of 2D channels 250 being formed using the same 2D material 110 layers (e.g., as in FIGS. 2-16), in FIG. 17 the two 2D channels 250 closer to the substrate 101 (e.g., around the first carrier nanosheet 115) can be formed using the 2D material 110 (e.g., just as in the stack in FIG. 2), but the two upper 2D channels 250 (e.g., around the second carrier nanosheet 115) can be formed using 2D material 111 layers instead of 2D material 110 layers. In addition, the material stack can also be changed with respect to the layer of gate metals being used. While the gate structure 235 of the lower transistor can utilize the gate metal 145 (e.g., just as in FIGS. 2-16), the gate structure of the upper transistor 100 can be built using a new gate metal 146.

As shown in FIG. 17, one 2D material/gate metal combination can be optimized for use with an n-type transistor structure (e.g., 2D material 110 and gate metal 145), while the other 2D material/gate metal may be optimized for use with a p-type structure (e.g., 2D material 111 and a gate metal 146). The carrier nanosheet 115 can be optional in some implementations. For example, 2D materials 110 and 111 can be in physical contact with, and/or be enclosed by, the high-k gate 140 material directly. As above, source and drain structures 215 and 220 can be formed by depositing S/D metal 135 into the etched out regions for S/D contacts, to form S/D structures 215 and 220. In implementations in which two different transistors 110 (e.g., transistors 100A and 110B) are fabricated, such as one on top of another, S/D structures 215 and 220 of one transistor 100 can be electrically isolated from the structures 215 and 220 of the other transistor 100.

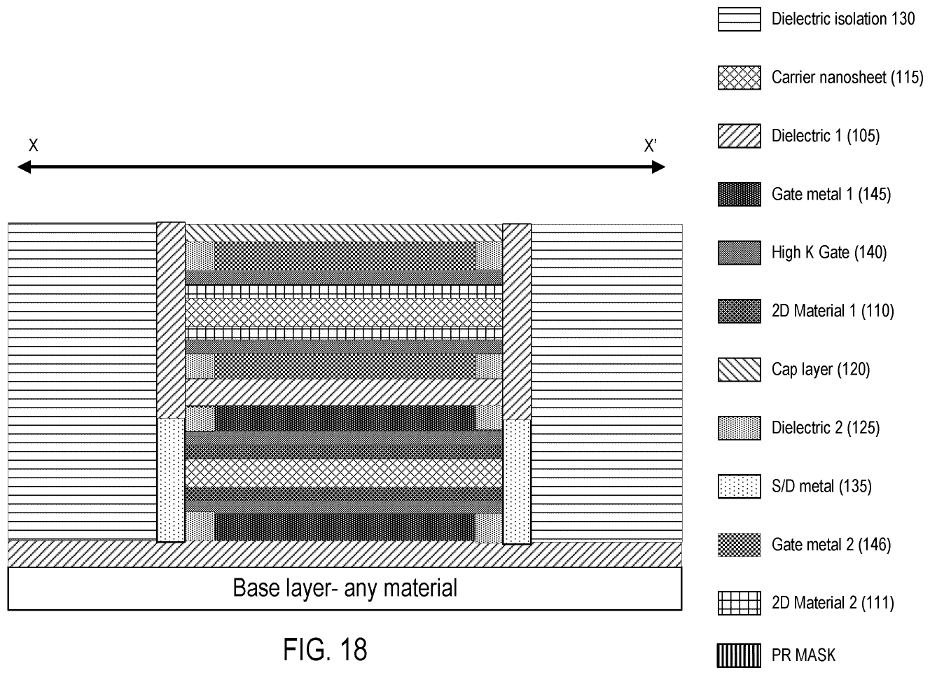

As shown in FIG. 18, S/D metal 135 can be etched out from the S/D contact regions of the top transistor structure (e.g., transistor 100B from FIG. 1B), leaving the S/D metal 135 in the of the S/D contact regions of the lower transistor structure (e.g., transistor 100A from FIG. 1A). S/D metal 135 can be left unetched up to a height of the trench that is above the first transistor structure (e.g., above the 2D materials 110 around the first carrier nanosheet 115). S/D metal 135 can be left unetched up to a height of about mid-way of the second gate metal 145 layer, above the 2D material channels 250.

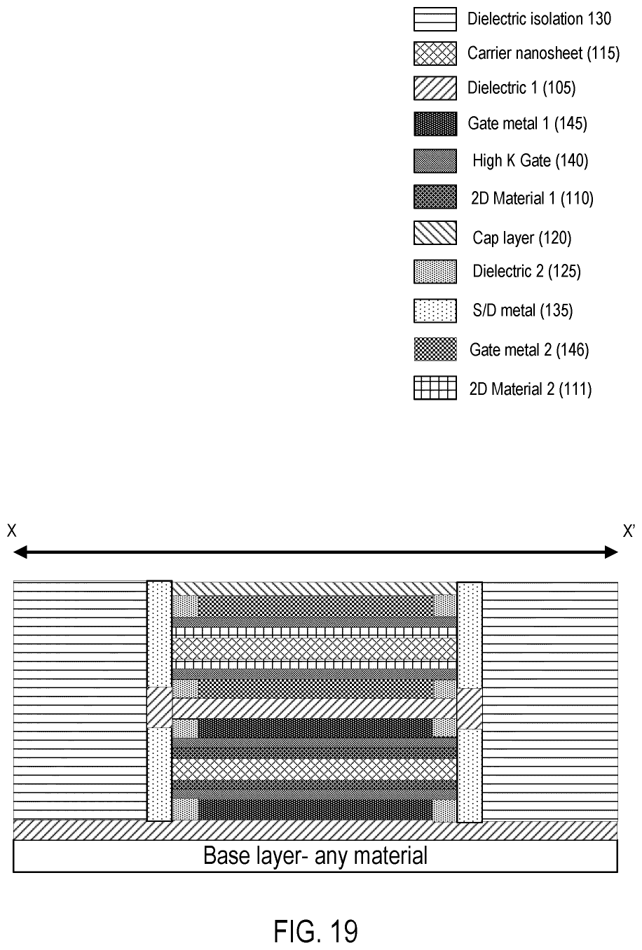

As shown in FIGS. 18-19, dielectric isolation between the S/D structures 215 and 220 of the bottom transistor (e.g., transistor 100A) and the S/D structures 215 and 220 of the top transistor (e.g., transistor 100B) can be deposited using dielectric 105. As shown in FIG. 19, dielectric 105 isolation between the S/D structures 215 and 220 of the top and bottom transistors 100A and 110B can extend from about the middle of the second gate metal 145 layer to about the middle of the first gate metal 146 layer. As shown in FIG. 19, upper S/D structures 215 and 220 can be formed around the top transistor structure so that it is electrically isolated from the S/D structures 215 and 220 of the bottom transistor structure. The S/D contacts for each transistor structure can include the same material (e.g., S/D metal 135) or it can comprise different or unique materials that can be optimized for the type of transistor required (e.g., n-type or p-type).

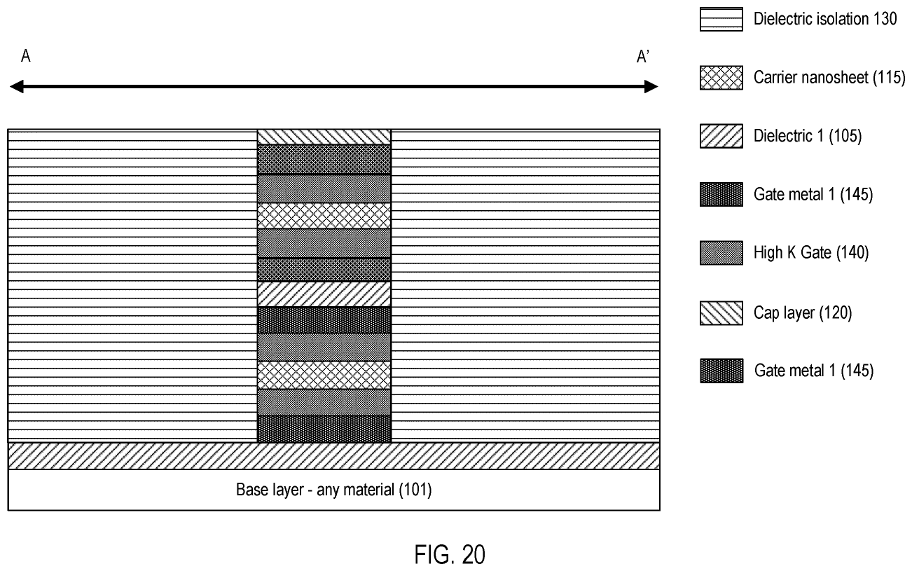

As shown in FIGS. 20, mask and etch steps can be used to create an access trench 260 that can be same or similar to the one describe above in connection with FIGS. 11-13. The isolation dielectric 130 that is adjacent the transistor structure can be patterned and etched in order to expose sidewalls of the underlying layers. A high-k gate 140 material can then be selectively deposited on exposed portions of the 2D materials 110 and 111 (which can be conductive materials) to form a high-k gate 140 dielectric layers, electrically isolating the 2D material 110 and 111 layers and preventing electrical shorting with gate metal 145. This can be implemented using the same or similar steps or techniques as those described in connection with FIG. 14.

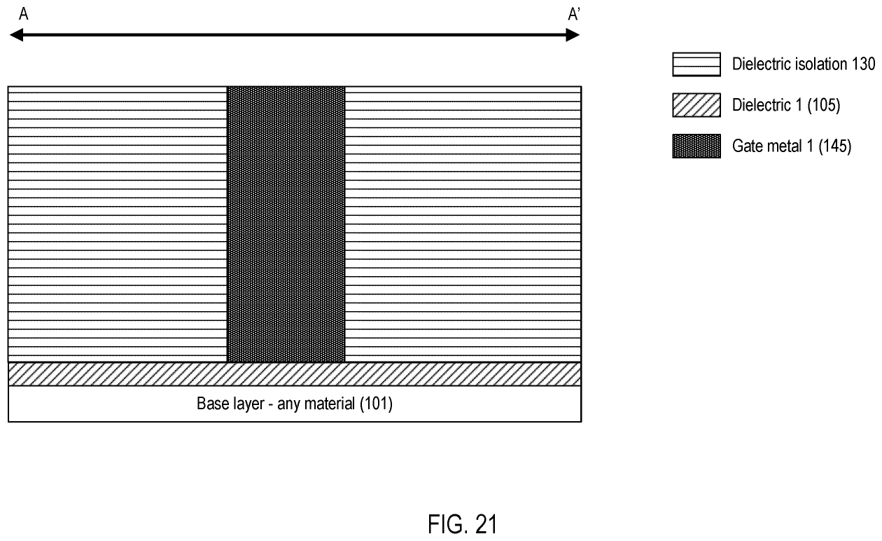

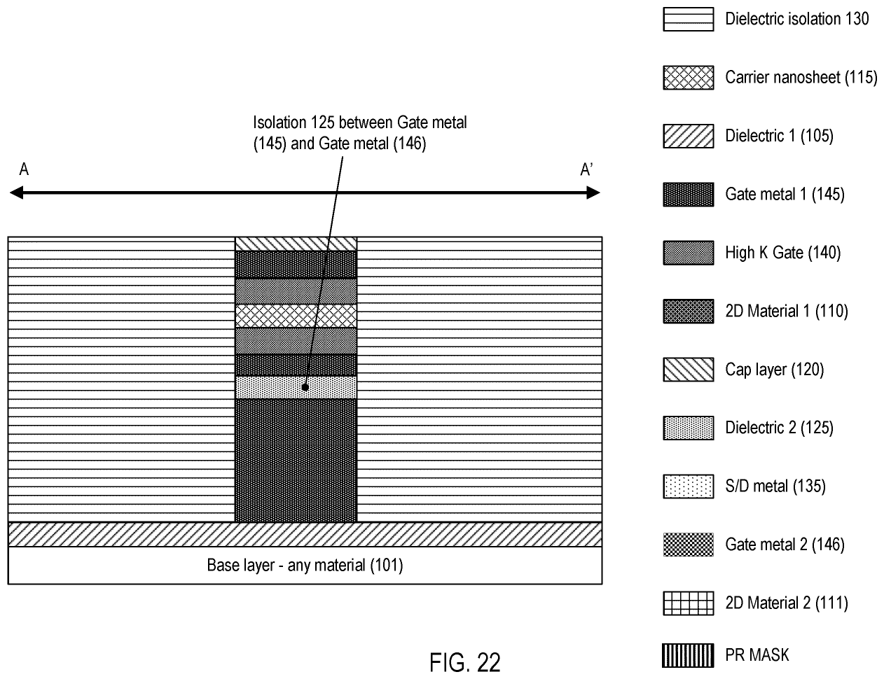

As shown in FIG. 21, a gate metal 145 can then be deposited or formed on exposed high-k 140 gate dielectric of the access trench 260 as shown in FIG. 21. In this implementation, a portion of the gate metal 145 can be removed (e.g., by atomic layer etch, ALE) to expose the dielectric layer separating the two transistor structures as shown in FIG. 22. This can be done using same or similar techniques or fabrication steps as those discussed in connection with FIG. 15. A dielectric isolation 125 can be deposited to isolate the gates from two different transistors 100 that are stacked one on top of another.

Shown in FIG. 22, the gate structure 235 of the lower transistor can be insulated from the gate structure 235 of the upper transistor with the electrically isolating material disposed between two gate structures 235. FIG. 22 illustrates a cross-sectional view from the access trench 260 along the A-A′ line showing different transistor structure that may be generally aligned with the dielectric 125 between the gate metal 145 layer of the lower transistor 100A and the gate metal layer 146 of the upper transistor 100B that to be deposited on top of the dielectric 125

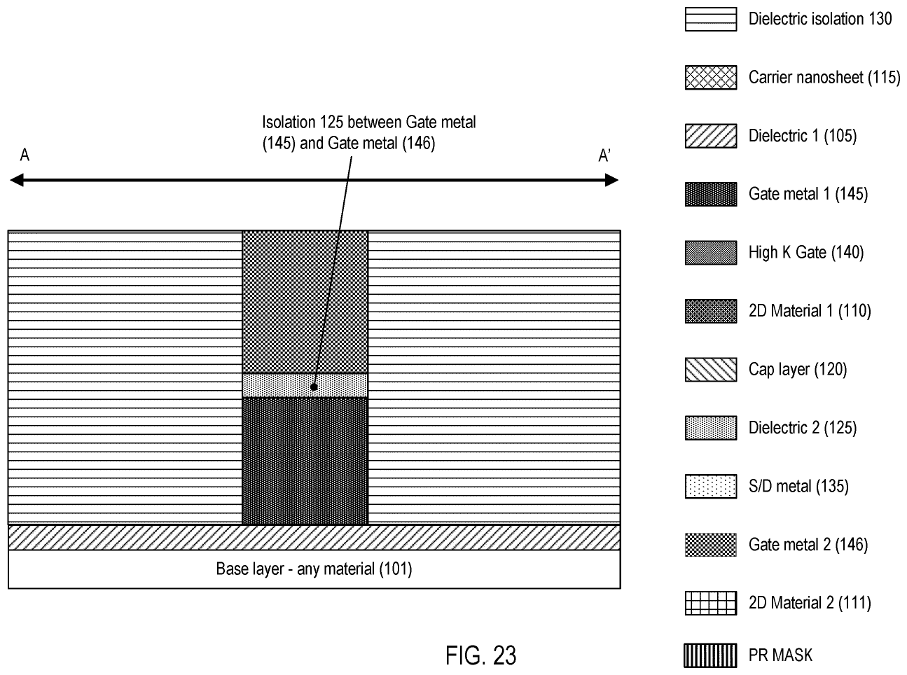

As shown in FIG. 23, gate metal 146 can be deposited in the access trench 260 on top of the dielectric 125 layer. Dielectric 125 therefore provides electrical isolation between the gate metal 145 of the lower transistor 100A and the gate metal 146 of the upper transistor 100B. As also shown from a cross-sectional view in FIG. 19, this structure includes an example of which is also illustrated in FIG. 1B.

Routing can then be provided according to conventional techniques to connect the source, gate, and drain to a circuit or a device of which the one or more transistors 100 can be a part. In one implementation all of the routing is directed to the same side of the structure stack. In other implementations, a portion of the routing may to each side of the transistor stack. For example, the first (or lower) transistor 100 structure (e.g., 100A) can be coupled to routing on the base layer side of the structure while the second (or upper) transistor 100 structure (e.g., 100B) can be coupled to routing on the opposite side of the structure from the base layer. In some implementations the base layer may be removed and one or both sides of the resulting stack of structures may be bonded to additional stacks or to other circuitry, e.g., by directly bonding the surface(s) of the structure to other dies or wafers.

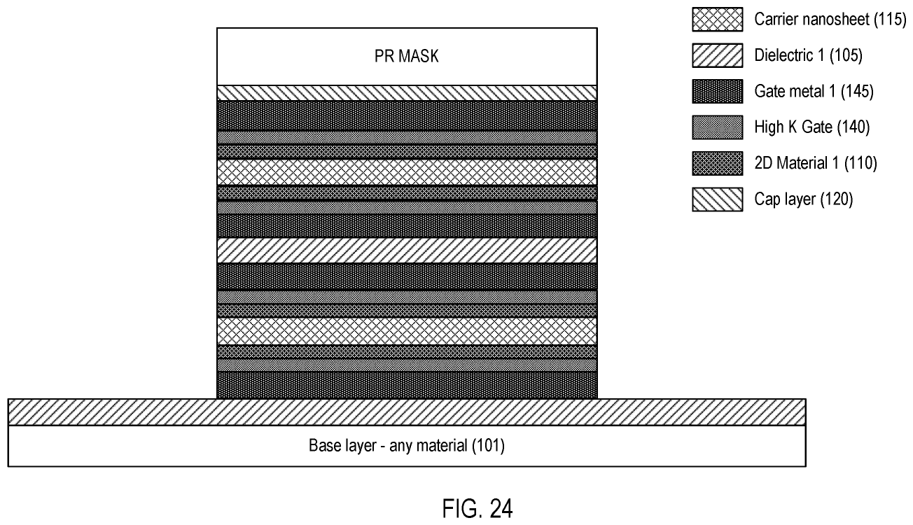

Referring now to FIGS. 24-38, an alternative process for forming a 3D transistor with 2D materials using in-situ stack is illustrated. The variations form structures similar to those shown in FIG. 1-23, but this time using modified GAA structures in which 2D channels 250 are surrounded or enveloped by gate structure 235 more fully. In some implementations, gate structure 235 surrounds each one of the 2D channels 250 all around the axis of the 2D channels 250 (e.g., 360 degrees around the length of each 2D channel 250).

FIG. 24 shows an example of a fabrication process for a 3D transistor in which GAA structure is formed around 2D channels 250 using a GAA alternative process that is related to one discussed in connection with FIGS. 1-16. In some implementation, the process can include implementation of the same steps as those shown or discussed in connection with FIGS. 1-16.

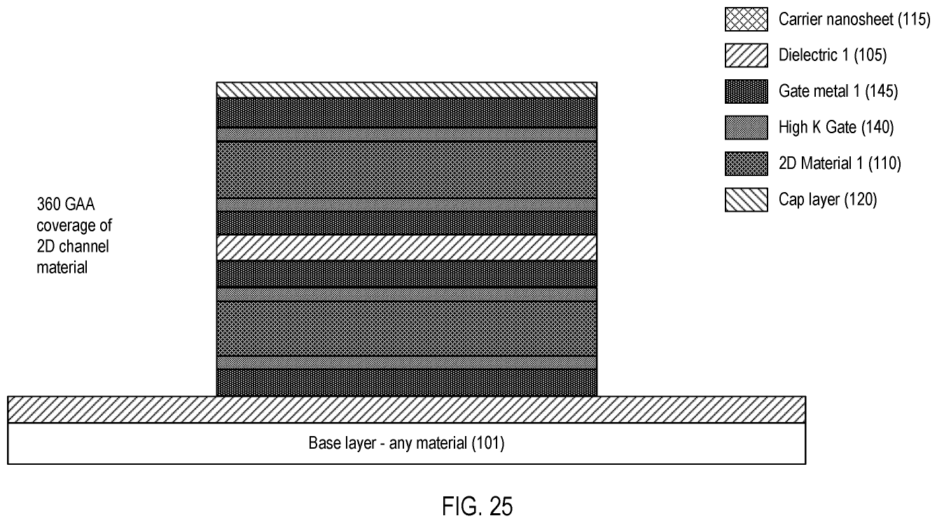

FIG. 25 shows a process that can start with FIG. 3 and complete a photoresist removal followed by selective 2D material 110 deposition on the exposed sides of the carrier nanosheets 115. 2D material 110 deposition can be a selective deposition, grown or otherwise applied exclusively onto the exposed surfaces of the carrier nanosheet 115 as a seed layer. Material properties of the carrier nanosheet 115 and 2D material 110 can be such that a monolayer of 2D material 110 can attach and form on the surface of the carrier nanosheet 115, but not other materials. The deposition can also cover the S/D structures 215 and 220 regions so that the ends of the carrier nanosheets 115 are coated with 2D material 110, which can provide an improved electrical conductivity between the S/D structures 215 and 220 to be completed and the ends of the 2D channels 250 to which S/D structures 215 and 220 are going to connect. While the illustrated example of this process shows 2D material 110, it is understood that 2D material 111, or any combination of 2D materials 110 and 111 can be used throughout this process, or any other process described herein, depending on the contemplated design.

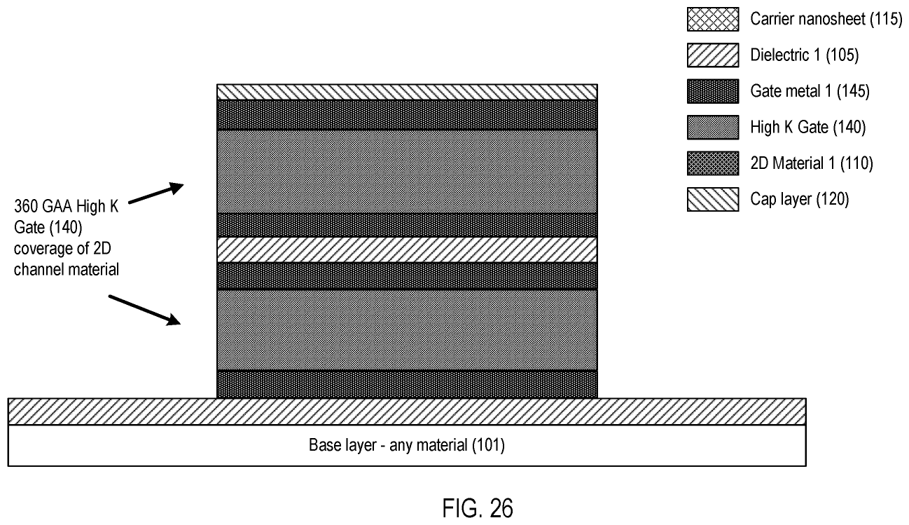

FIG. 26 shows selective high-k 140 material deposition over the exposed 2D material 110 exposed surfaces that were deposited or formed on top of carrier nanosheet 115 in fabrication steps taken in connection with FIG. 25. More specifically, high-k 140 gate dielectric can be selectively deposited on top of the 2D material 110 surfaces, covering and insulating them on all exposed sides. This can ensure that 2D material 110 layers remain electrically insulated from the gate metal 145 to be deposited on top of the high-k gate 140 dielectric.

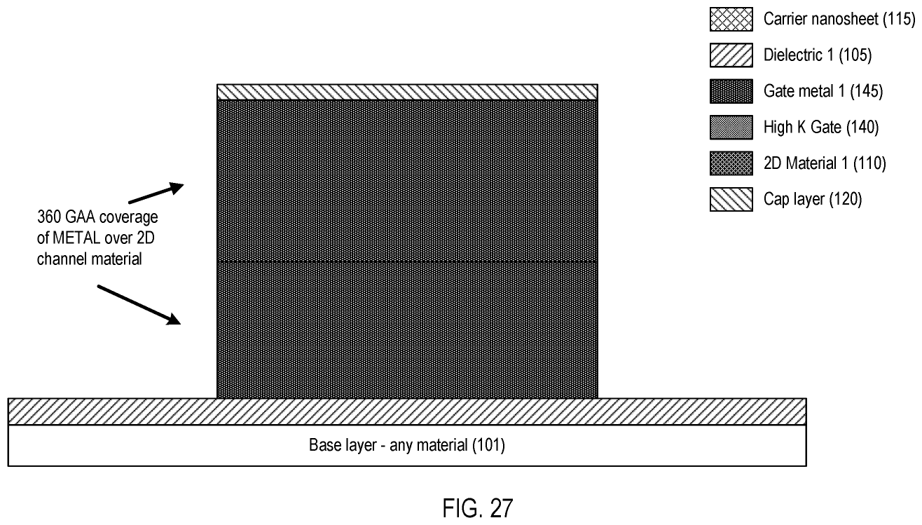

FIG. 27 shows gate metal 145 deposited over the entire side of the structure. For example, gate metal 145 can be applied to cover the entire exposed sides of the 2D channel 250 regions. This can be followed by an etch to remove metal from the substrate dielectric region. As the gate metal 145 can cover all the exposed areas in FIG. 26, the gate metal 145 can make a contact with the layers of gate metal 145 within the structure as well as on the side. Remaining trapped, but electrically isolated inside, is the layer of high-k gate 140 dielectric that envelops or surrounds 2D material 110 layers. The gate structure 235 surrounding the 2D material 110 layers can thereby form 2D channels 250. Gate structure 235 can also form a common gate structure 235 connection that forms a single electrical contact controlling and enclosing all 2D channels 250 of the structure. The gate structure 235 can enclose or surround the 2D channels 250 at least from beneath the channels, above them and at least one of the sides (e.g., areas formed by the length and the thickness of the carrier nanosheets 115) as shown, for example, in FIGS. 24-27.

In another implementation, the same fabrication steps and techniques used to enclose 2D material 110 layers with the gate structure 235 shown and discussed in connection with FIGS. 24-27 can also be applied with respect to the opposite side of the structure (e.g., the side of the structure that is opposite of the side illustrated in FIGS. 24-27). The gate structure 235 can therefore also be formed using the same steps on all four sides around each of the 2D channels 250 (e.g., around the bottom, top, and both sides of the carrier nanosheet 115, excluding only the path to and from S/D structures 215 and 220), thus enclosing the 2D channels 250 360 degrees around each of the 2D channels 250.

In some implementations, by applying the gate structure 235 around the sides, the gate structure can also extend to the two distal ends of the structure (e.g., at the S/D structure 215 and 220 region). Alternatively, gate structure 235 can cover any length of the 2D material 110 and/or 111 layers less than the entire length of the structure. As needed, material can then be removed from S/D regions in order to form S/D structures 215 and 220 in those regions.

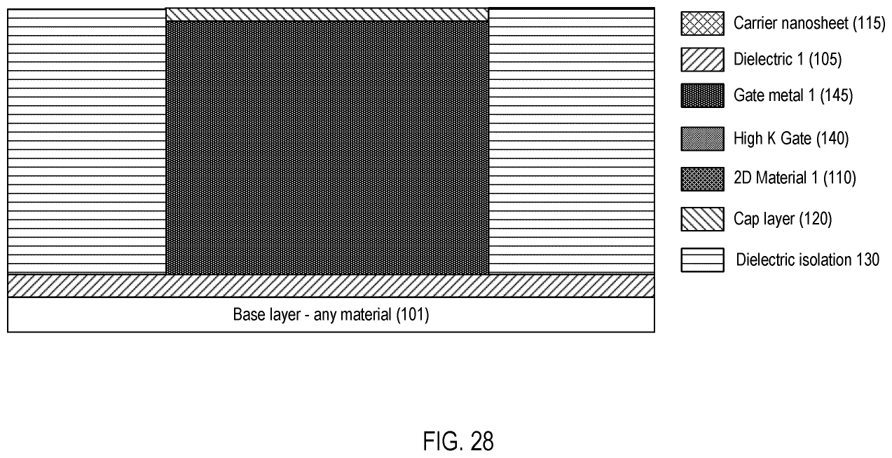

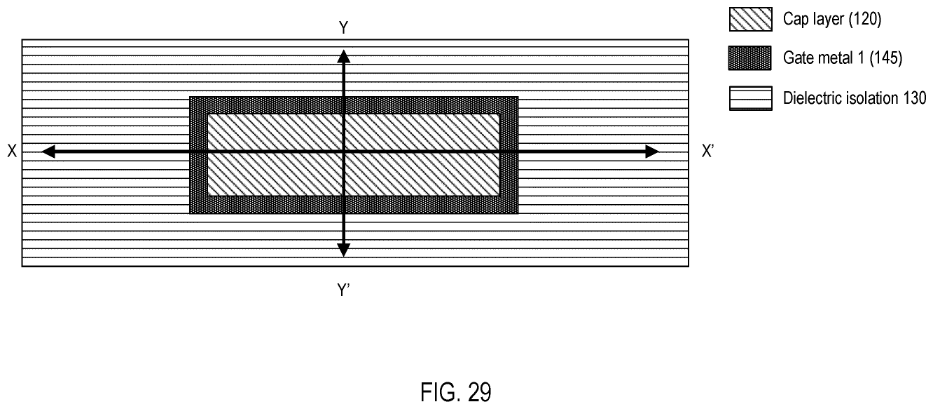

FIG. 28 shows dielectric isolation 130 being formed around the structure. This can be followed by a CMP. FIG. 29 shows a top view of the structure of the transistor 100 and its surrounding (e.g., dielectric isolation 130) after the completion of the above fabrication step. FIG. 29 shows the gate structure 235 being formed all around the transistor structure, while on top of the structure is the cap layer 120.

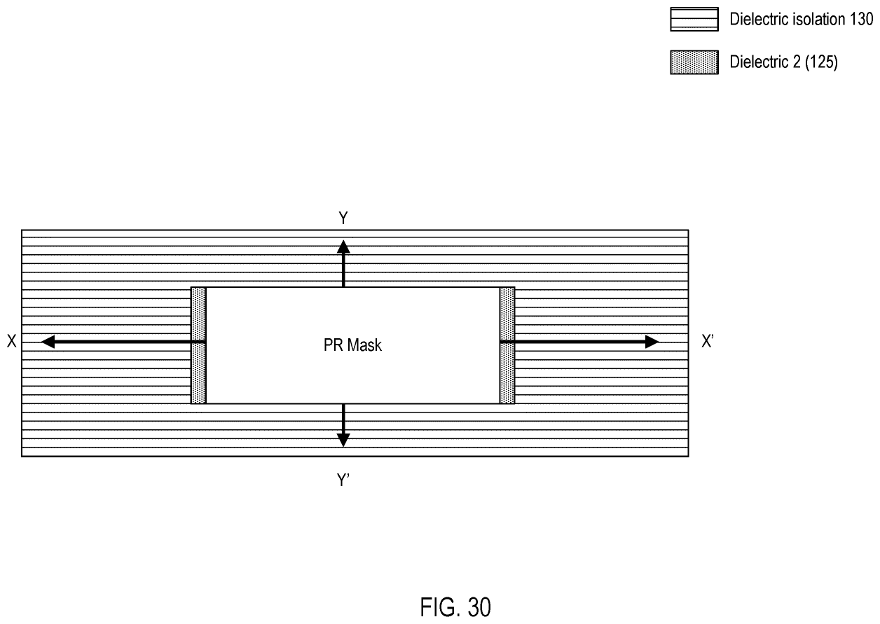

FIG. 30 shows a top view of a PR mask being applied for the directional downward etch in the following fabrication step, where the PR mask covers the corners around which the dielectric can be 125 is applied. This can allow for a directional downward etch of the S/D regions without disturbing the dielectric 125 that can be inserted around the corners of the structure to prevent electrical shorting between the outer surfaces of the S/D structures 215 and 220 to be formed and the gate structure 235.

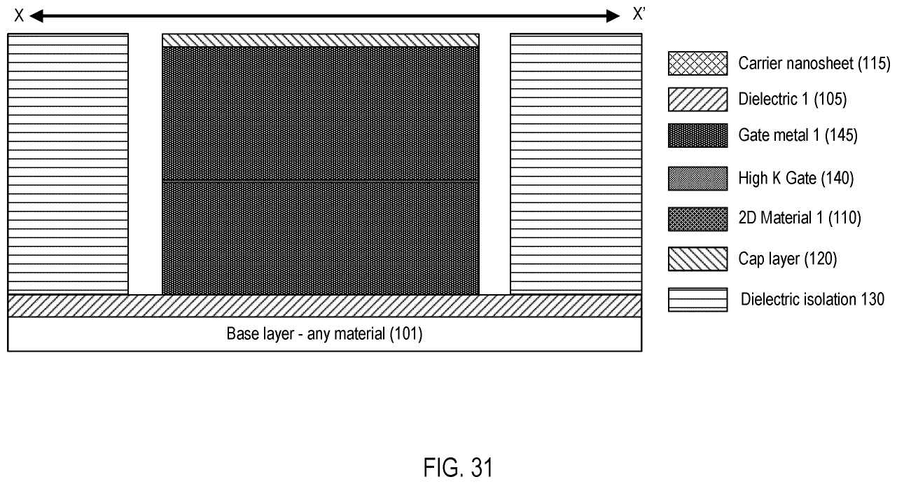

FIG. 31 shows PR masking and etching of the dielectric isolation 130 that abuts the distal ends of the transistor 100 structure in which S/D structures 215 and 220 are to be formed. The PR mask can then be removed, leaving only the trenches for the S/D structures 215 and 220.

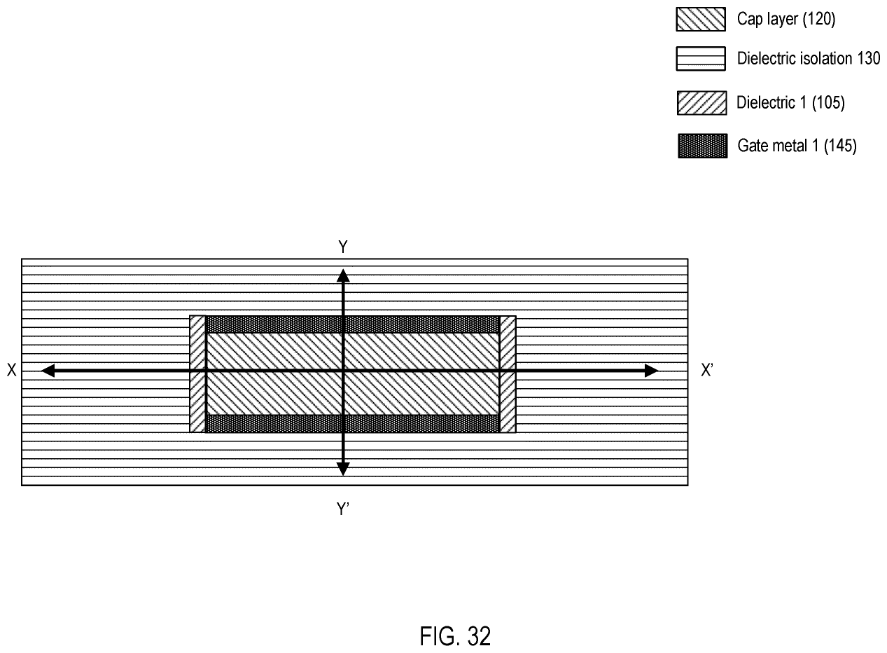

FIG. 32 shows a top view of the structure following the earlier fabrication step in which the masking and etching of the dielectric isolation 130 can be implemented with respect to the S/D structure 215 and 220 regions.

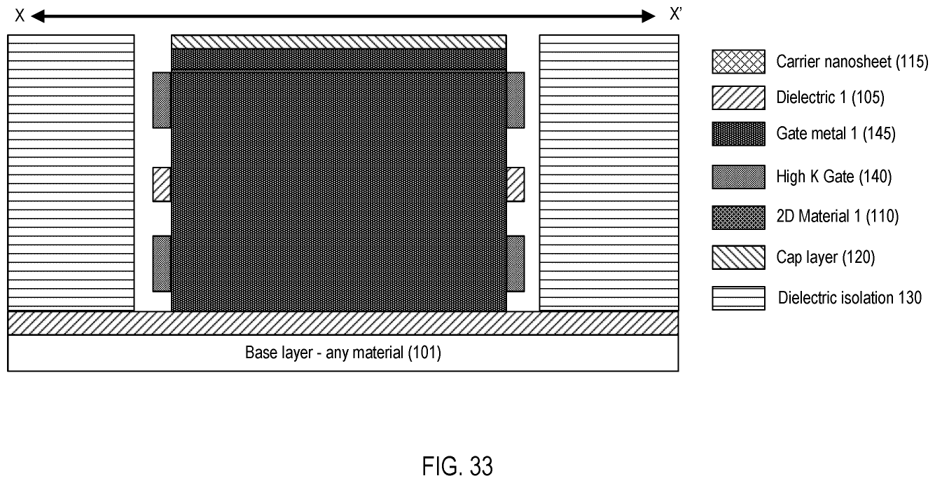

FIG. 33 shows gate metal 145 indent etch, followed by a removal of the PR mask. This can be implemented, for example, using the same or similar techniques as those discussed in connection with FIGS. 7-8.

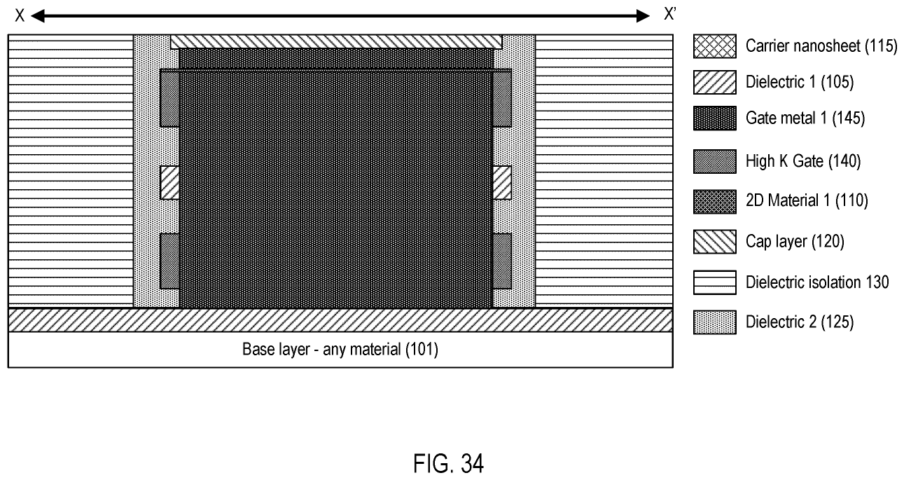

FIG. 34 shows dielectric 125 deposited into the earlier etched out trench in the S/D regions. Dielectric 125 can fill in all the gaps, including indented gaps in the structure. Dielectric 125 can serve as an electrical insulation between the gate structure 235 and S/D structures 215 and 220 to be formed.

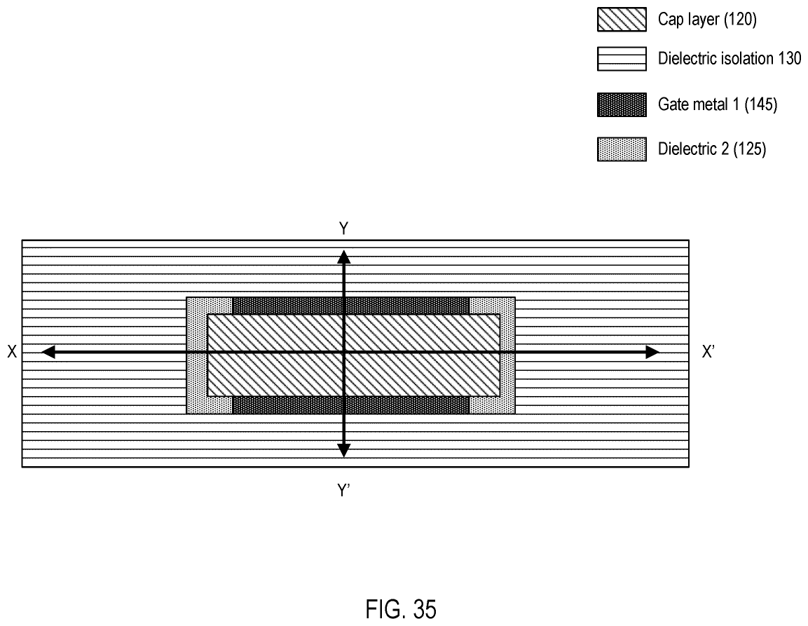

FIG. 35 shows a top view of an implementation in which the corners of the S/D regions were also etched out. By applying dielectric 125 around the structures, a layer of dielectric 125 can be inserted so as to prevent electrical shorting between the outer surfaces of the gate structure 235 and the S/D structures 215 and 220 to be formed.

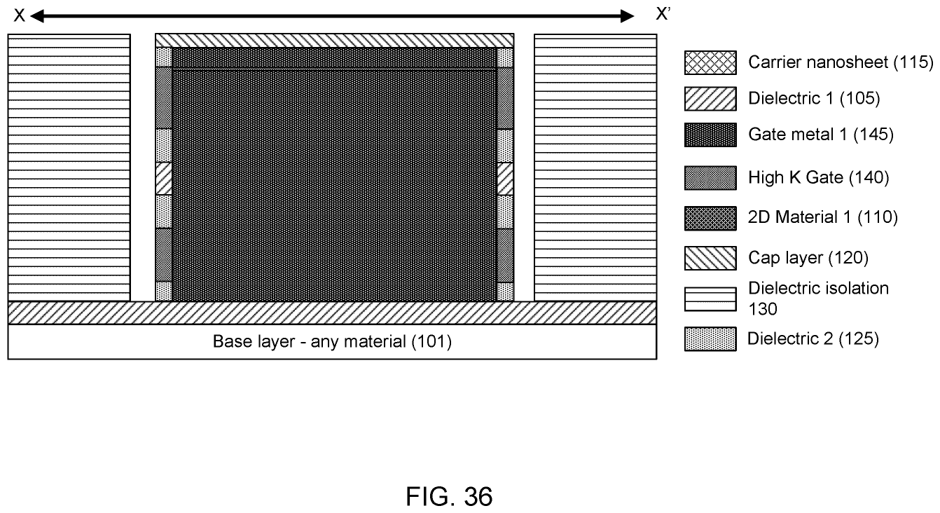

FIG. 36 shows extending of the cap layer 120 to cover the distal ends of the structure that are going to abut the S/D structures 215 and 220 in order to protect them from the etch. In comparison with the cap layer 120 in FIGS. 32 and 33, the cap layer 120 in FIG. 36 is extended further outward towards the S/D regions to cover the ends of the structures that will interface with S/D structures 215 and 220. A downward etch is then performed into the dielectric 125 of the S/D regions at the distal ends of the structures, providing the space for the S/D metal 135 to be deposited. Any resist can then be performed after the etch and CMP can be completed, as needed, to polish the top surface of the structure and any leftover material.

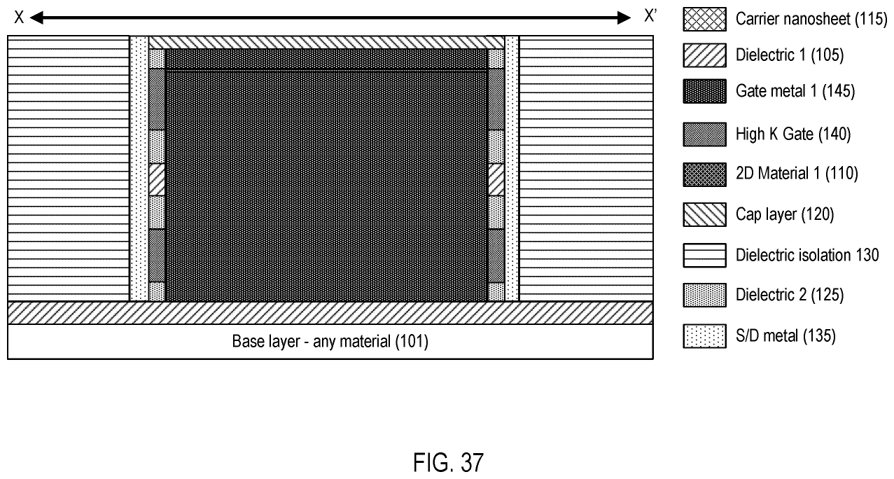

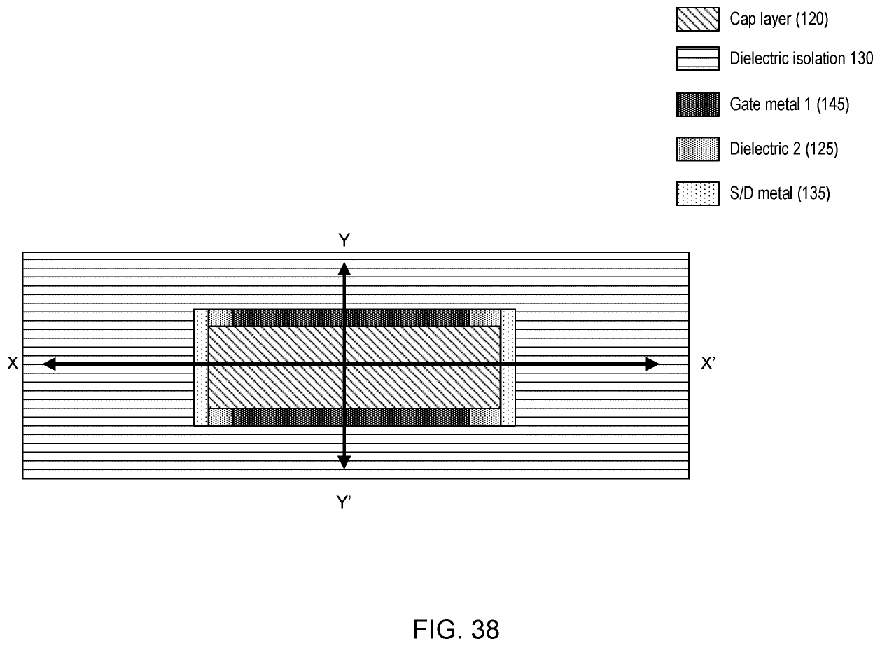

FIG. 37 shows S/D metal 135 deposition into the S/D regions. S/D metal 135 can be deposited to fill the entire etched out trench and make the contact with the ends of the 2D material 110 (or 111) layers to form 2D channels 250. S/D metal 135 deposition can be followed by a CMP. This fabrication step can complete this particular implementation of the transistor structure. FIG. 38 shows a top view of the completed example transistor, following the completion of the fabrication step at FIG. 37.

Example transistor 100 completed in FIGS. 37 and 38 shows a transistor 100 having S/D structures 215 and 220, forming a source and the drain of the transistor. The S/D structures 215 and 220 can each include one or more sidewalls and can extend vertically upwards with respect to the surface of the base layer 101 or a dielectric layer thereon, such as a dielectric 105. 2D channels 250 formed along carrier nanosheets 115 are formed extending horizontally between the S/D structures 215 and 220 (not shown in FIG. 37, but visible in FIG. 24). Each carrier nanosheet 115, in this example structure shaped as a cuboid, has 2D channels 250 formed on at least four of its surfaces along the length of the carrier nanosheet 115, including: the bottom surface, the top surface and the two sidewall surfaces formed between the length and the thickness dimensions of the carrier nanosheet 115. The illustrated structure can therefore include 2D channels 250 formed on eight sides of carrier nanosheets 115. On each carrier nanosheet 115, 2D channels 250 can each be enclosed or surrounded on four sides by a gate structure 235. The gate structure 235 can be a GAA structure 235 that can include a high-k gate 140 material in physical contact with the 2D material 110 (or 111) layers on all sides, followed by gate metal 145. In the illustrated configuration, the only two sides around which gate structure 235 is not formed are the two sides leading to and from the S/D structures 215 and 220. This example transistor can include up to eight times the drive strength given due to its 2D channels 250 being formed on eight surfaces of carrier nanosheets in the event that the thickness of the carrier nanosheet 115 is the same or similar to its width. In the event in which the thickness of the carrier nanosheet 115 is significantly smaller than its width, the drive strength of the transistor 100 can still be more than quadrupled in this architecture. This can lead to improved control and performance.

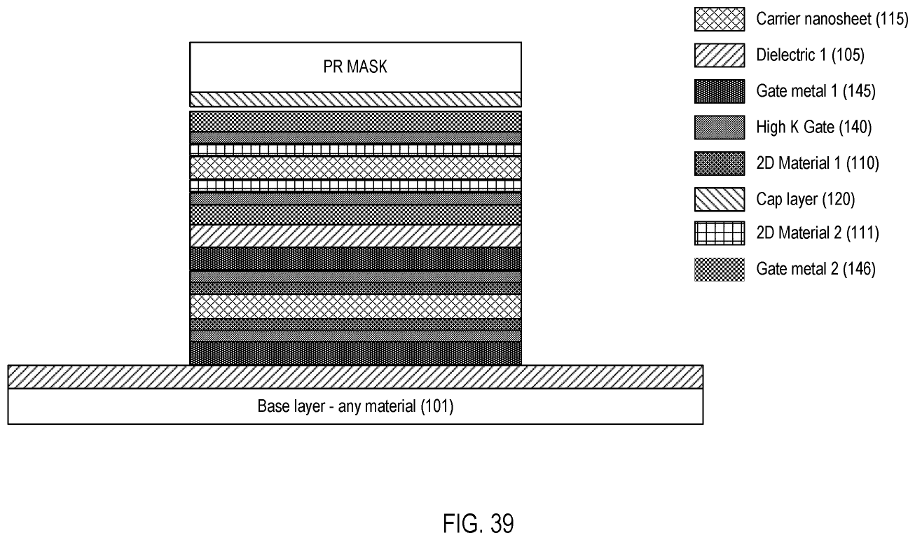

Referring now to FIGS. 39-51, illustrated is an alternative process for fabricating an example structure with multiple transistors (e.g., transistors 100A and 100B) vertically stacked on top of each other and having their own independently controlled GAA gate structures 235A and 235B using the in-situ approach. As with other example structures with multiple transistors 100A and 100B, different kinds of 2D material layers can be used to form 2D channels 250, such as 2D material 110 layers that for n-type transistor channels and 2D material 111 layers for p-type transistor channels. This structure can also utilize two different gate metals, such as the gate metal 145 and gate metal 146, where the gate metals can include the same or different materials that can be electrically isolated from each other, allowing for independent control of transistors 100A and 100B via their independent GAA gate structures 235.

FIG. 39 can begin with a material stack similar to the one shown, for example, in FIG. 3, but using different gate metals and different 2D materials for the upper and lower transistors. The material structure in FIG. 39 can include, for example, the same or similar structure or stack as the one discussed in connection with FIG. 17. A PR mask can be placed on top of the structure to complete an etch around the structure.

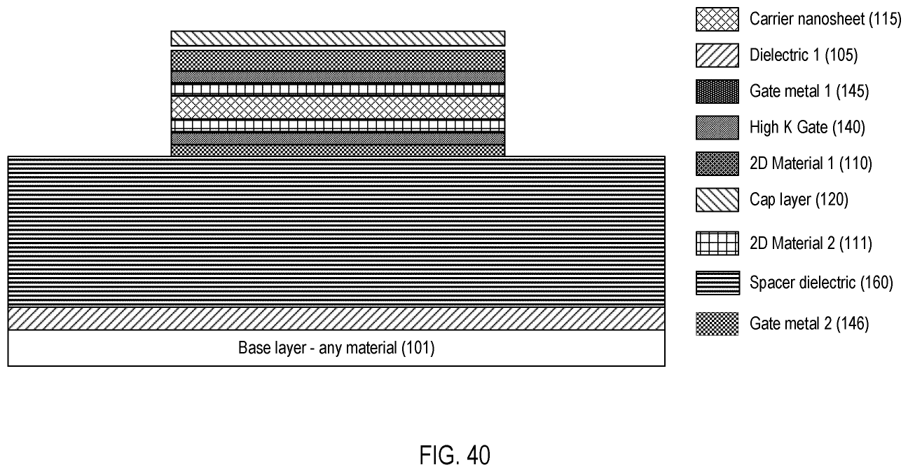

FIG. 40 shows removal of the PR mask after a spacer deposition, which can be implemented with, for example, a dielectric shown in the legend as the spacer dielectric 160. Spacer dielectric 160 can be deposited all around the structure, using the PR mask to prevent its deposition on the structure itself. The height of the spacer deposition can be up to about the mid-point of the third metal gate layer from the base (e.g., the lower, or the first, gate metal 146), thus exposing only the sidewall (or sidewalls) of the top (e.g., second from the base) dielectric nanosheet 115 on which 2D material 111 is provided.

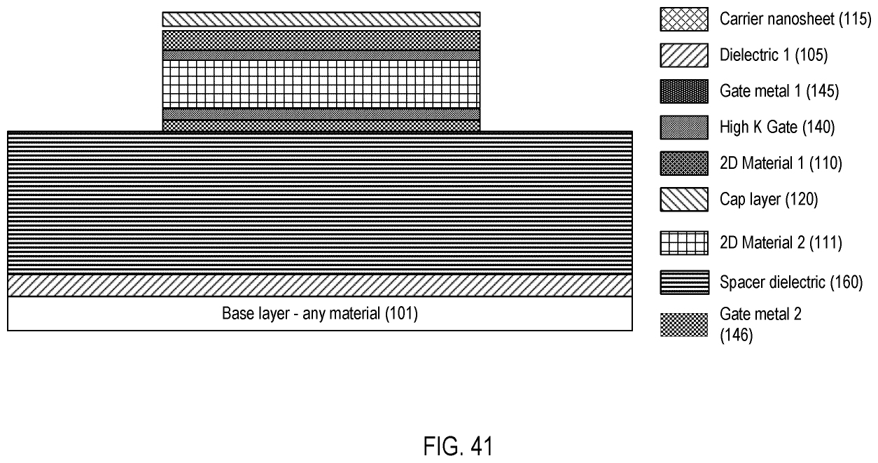

FIG. 41 shows application of a selective deposit of 2D material 111 on the sidewall(s) of the top carrier nanosheet 115. Applying 2D material 111 can be done, for example, as a seed layer on the carrier nanosheet 115, comprising, for example, a monolayer of 2D material 111 that can be deposited, grown, or otherwise formed. Spacer dielectric 160 can prevent 2D material 111 deposition on the bottom half of the structure on which a different transistor (e.g., transistor 110A) can be formed. This can done be on the illustrated side of the structure, but also on the opposite side (not illustrated), so as to form the GAA.

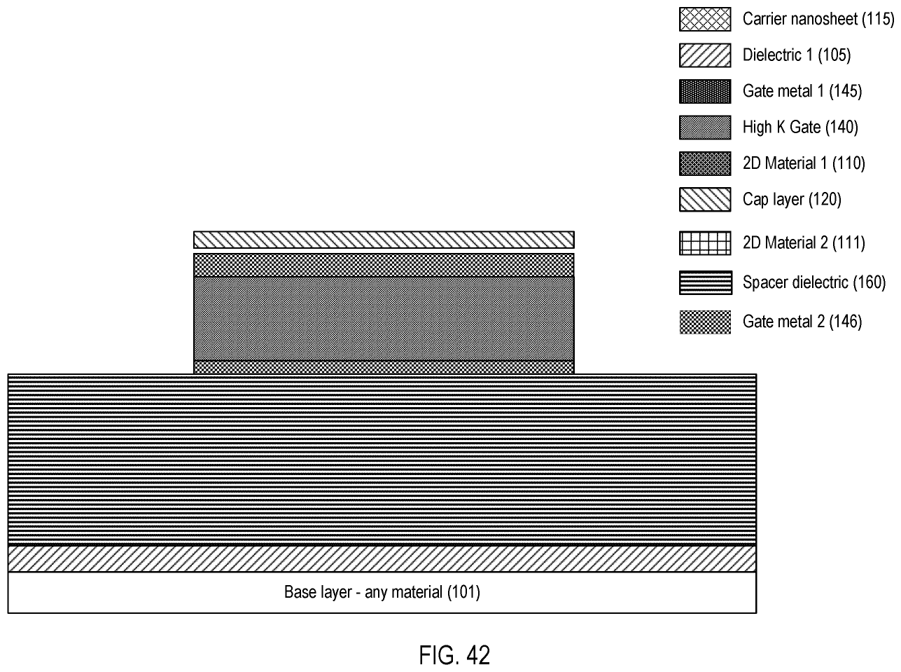

FIG. 42 shows an application of a selective high-k gate 140 material on the sidewall sections on which the 2D material 111 was applied in the prior step of the fabrication. High-k gate 140 material can cover all of the 2D material 111 layer and entirely encircle, surround or envelop it. This can done be on the illustrated side of the structure, but also on the opposite side (not illustrated), so as to form the GAA type of gate structure 235.

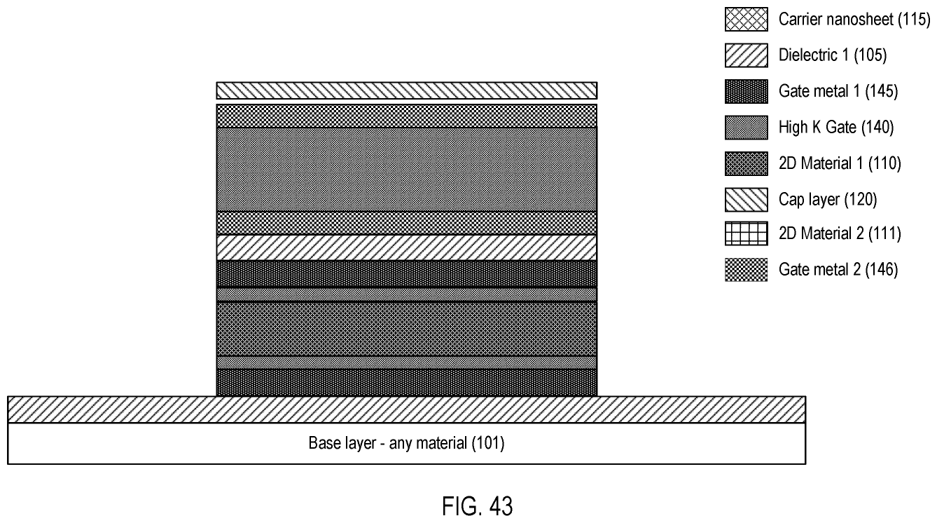

FIG. 43 shows the spacer dielectric 160 removed, such as via selective etching, to expose region of the transistor 100A (i.e. the lower transistor) after which the processing steps that are same or similar to those completed in connection with transistor 100B (e.g., upper transistor) discussed in FIGS. 41-42 can be implemented. Selective deposition of 2D material 110 can be applied on the first carrier nanosheet 115 to cover the lower NMOS sidewall channel region with 2D material 110.

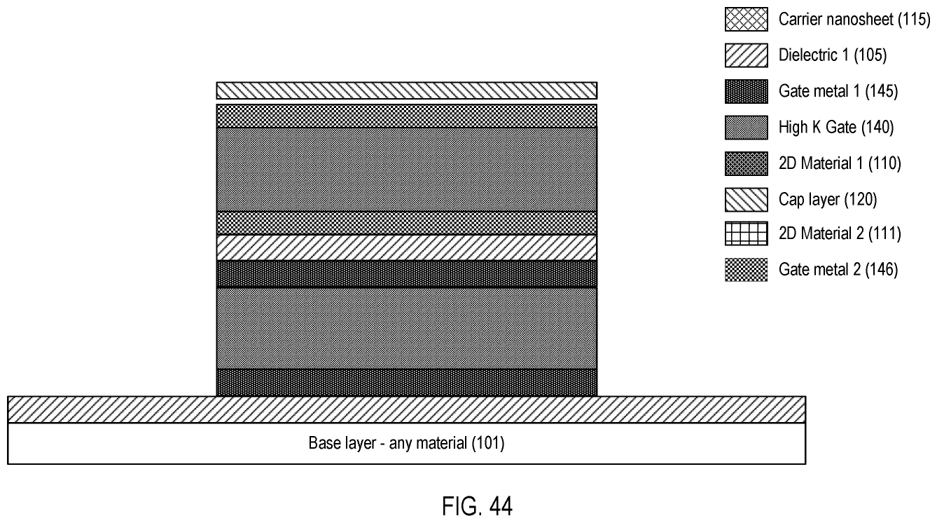

FIG. 44 shows selective high-k gate 140 deposition on the 2D material 110 sidewall layer to cover the 2D channel 250 of the transistor 100. This can be done using the same or similar process as in FIG. 42.

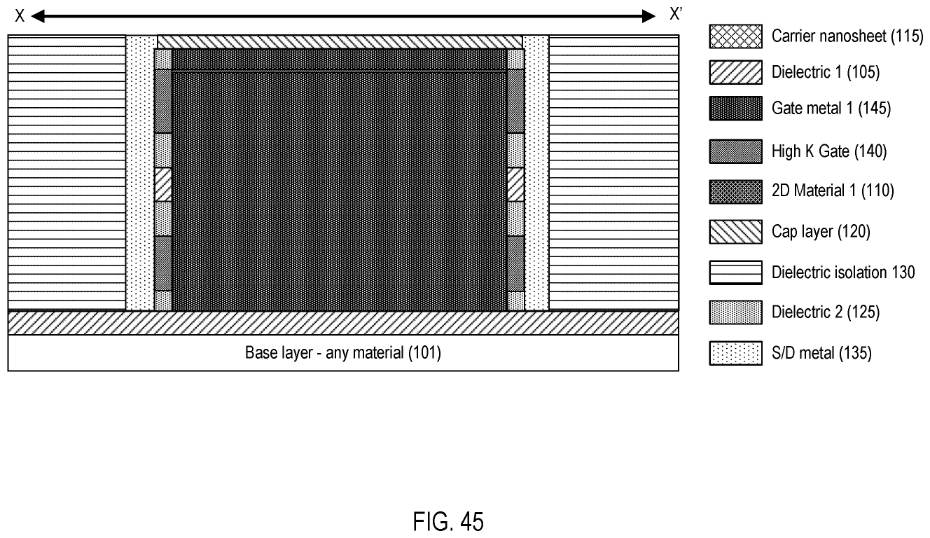

FIG. 45 shows deposition of the gate material 145 and of S/D metal 135 to form S/D structures 215 and 220 at the distal ends of the structure. This can be followed by a CMP. Deposition steps for forming the gate material 145 and the S/D contacts can be completed using the same or similar steps or techniques discussed in connection with FIGS. 30-37.

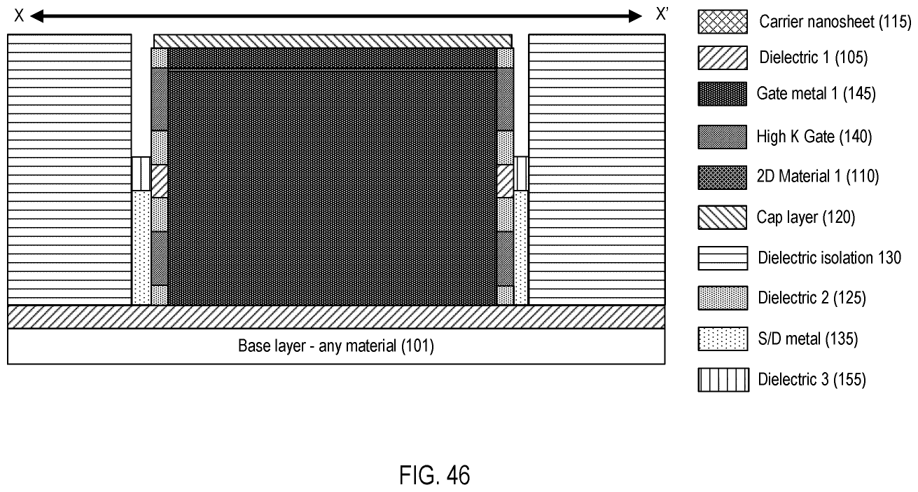

FIG. 46 shows partial etching of the upper half of the S/D metal 135 in order to insert a layer of dielectric 155 to electrically isolate the lower S/D structures 215A and 220A of the lower transistor 110A from the upper S/D structures 215B and 220B to be implemented for the upper transistor 100B. This can be done using the same or similar techniques or fabrication steps discussed, for example, in connection with FIGS. 18-19.

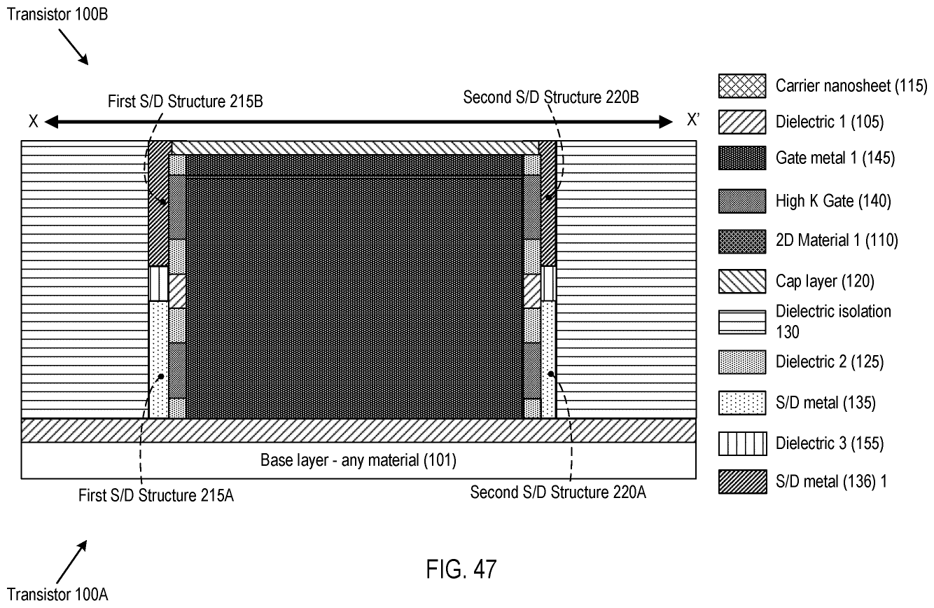

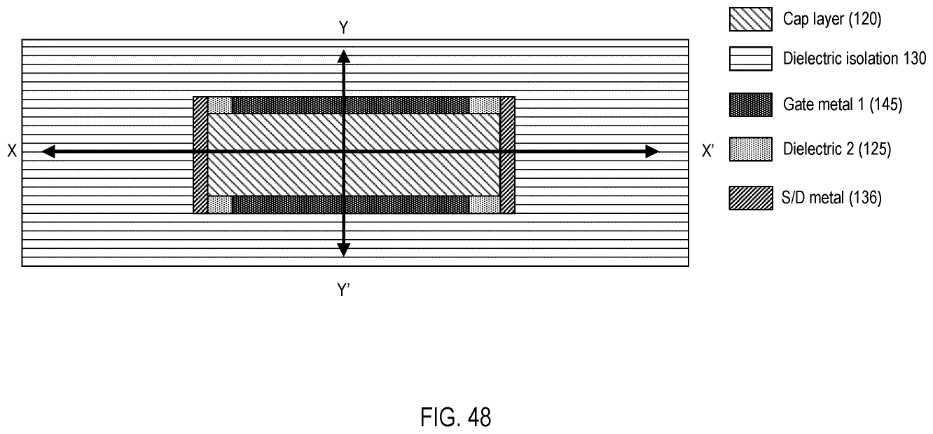

FIG. 47 illustrates an embodiment in which the S/D structures 215A, 220A, 215B and 220B are completed. The material used for S/D structures 215A and 220A can be the same or different than the material used in S/D structures 215B and 220B. On top of the deposited dielectric 155, in the S/D region trenches, a layer of S/D material 136 can be deposited to form S/D structures 215B and 220B of the top transistor 100B. The resulting implementation ensures that S/D structures 215A and 220A of the lower transistor 100A are electrically independent from the S/D structures 215 and 220B of the upper transistor 100B. FIG. 48 shows top view after completion the completion of the fabrication steps in FIG. 47 in which S/D metal 136 is visible from the top view in the S/D regions of the structure.

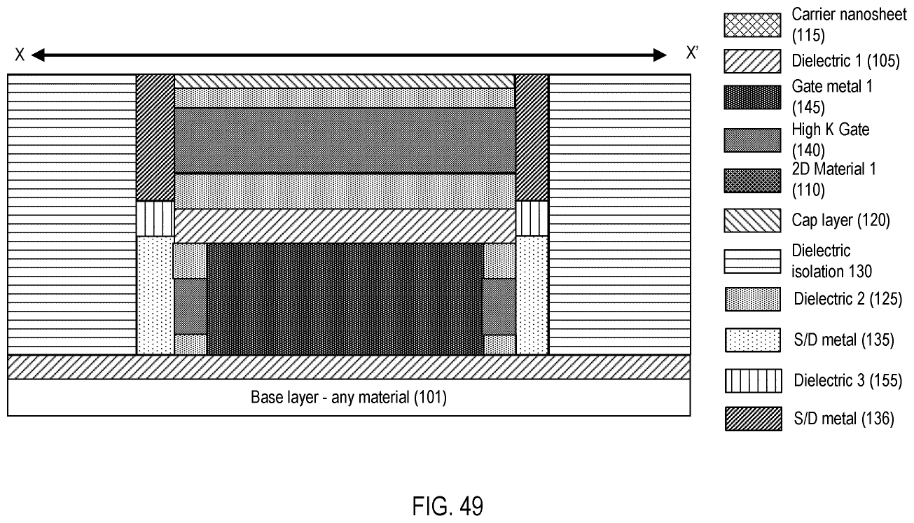

FIGS. 49-51 show formation of the two independent GAA gate structures 235A and 235B for the transistor 100A and 100B. Starting from the gate metal 145 covering the entire side of the structure, shown in FIG. 47. In FIG. 49 a selective metal etch is implemented to reduce the height of the gate metal 145. The gate metal 145 can be reduced so as to cover only the lower transistor 100A. This can be done using, for example, techniques and fabrication steps similar to those discussed in connection with FIG. 22.

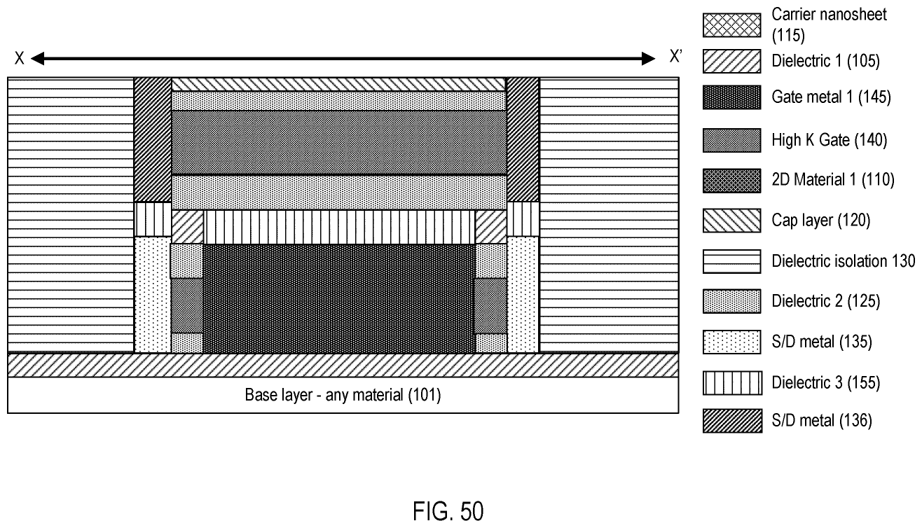

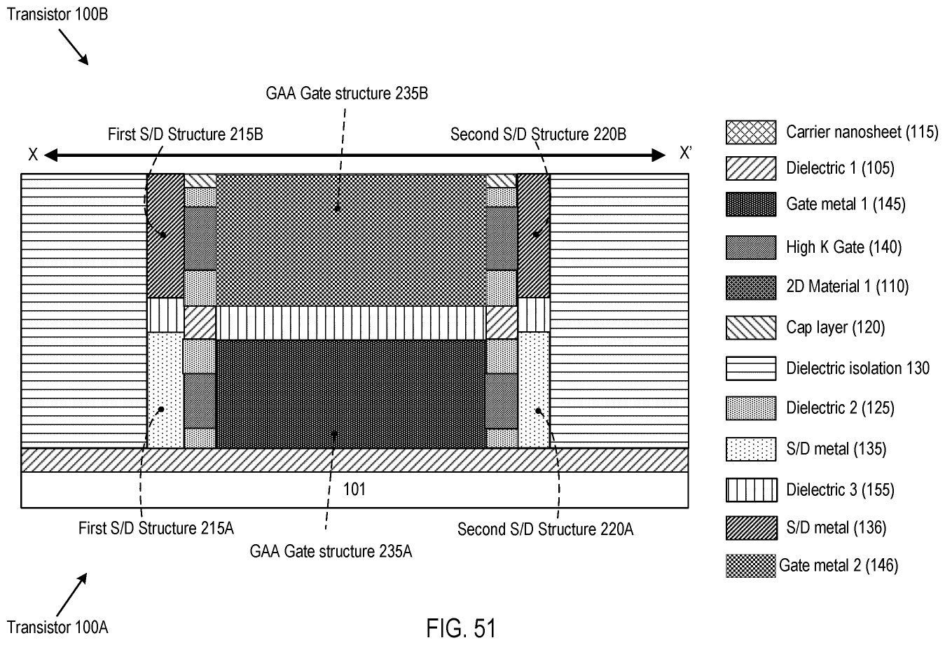

FIG. 50 shows deposition of dielectric 155 on top of the gate metal 145 of the transistor 100A in order to provide an electrical isolation with the gate metal 145 and the gate metal 146 of the transistor 100B. This can be done, for example, using the steps and techniques such as those discussed in connection with FIGS. 22-23. Once this step is completed, transistor 100A (e.g., the bottom transistor) can have its 360 degree formed GAA-type gate structure 235A completed (not illustrated in FIG. 50, but shown in FIG. 51).

FIG. 51 shows deposition of gate metal 146 to complete the top GAA gate structure 235B for transistor 100B. Following this step a CMP can be completed to complete the transistor 100B. CFET structures 100A and 100B can now be both completed as a NMOS transistor 100A and PMOS transistor 100B, along with their 2D channels 250, formed with 2D material 110 for the NMOS transistor 100A and 2D material 111 for the PMOS transistor 100B. The GAA gate structures 235A and 235B for transistors 100A and 100B can be electrically isolated from each other, just as with the S/D structures 215A and 220A with respect to the S/D structures 215B and 220B, thereby allowing transistors 100A and 100B to be independently controlled and operated.

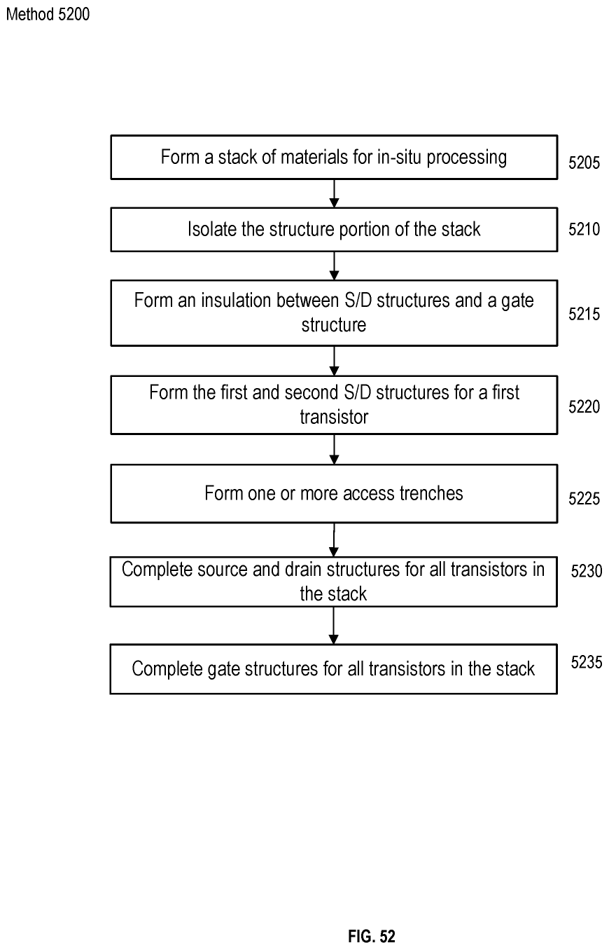

Referring now to FIG. 52, a flow diagram of an example method 5200 for fabricating one or more transistor 100 structures using one or more 2D material channels 250 implemented using in-situ 3D horizontal nanosheet formation. In some aspects, the method 5200 relates to in-situ fabrication of a single 3D transistor 100 having one or more 2D material channels 250. In some aspects, the method 5200 relates to in-situ fabrication of multiple 3D transistors, stacked on top of each other, each using 2D material channels 250.

The method 5200 of FIG. 52 can include a series of steps from 5205 to 5235. Step 5205 can include forming a stack of materials for in-situ processing. Step 5210 can include isolating the structure portion of the stack. Step 5215 can include forming an insulation between source/drain structures and a gate structure. Step 5220 can include forming the first and second source/drain structures for a first transistor. Step 5225 can include forming one or more access trenches. Step 5230 can include completing source and drain structures for all transistors in the stack. Step 5235 can include completing the gate structures for all transistors in the stack.

Step 5205 can include forming a stack of materials for a transistor structure. The stack can include a plurality of layers of materials on top of a substrate 101. The substrate 101 can include a semiconductor substrate or any other material substrate, including glass, ceramic, metal or any other substrate discussed herein. The stack of materials can include any number of layers of dielectric, metal, 2D materials or other materials discussed herein or known or used in the industry. The material stack can include a layer of sacrificial material or any other material that can be fully or partially etched or removed during the process, such as dielectrics 105, 125, 130 and 160, as well as high-k gate 140 dielectric and gate metals 145 and 146

A stack of materials can be formed on top of a substrate 101. The material stack can include several material layers of various thicknesses and types. The stack can include a first layer of dielectric 105, on top of which a first layer of gate metal 145 (or 146) can be formed, on top of which a layer of high-k gate 140 can be formed, on top of which a layer of 2D material 110 (or 111) can be formed, on top of which a carrier nanosheet 115 can be formed, on top of which a second layer of 2D material 110 (or 111) can be formed, on top of which a second layer of high-k gate 140 can be formed, on top of which a second layer of gate metal 145 (or 146) can be formed, on top of which a second layer of dielectric 105 can be formed. In the implementations in which a single transistor 100 having 2D channels 250 formed with only a single carrier nanosheet 115 is contemplated, the stack can be completed at this point with a cap layer 120 on top.

In the implementations in which two carrier nanosheets 115 are used, such as when four or more 2D channels 250 are contemplated, instead of adding the cap layer 120 on top of the second layer of dielectric 105, additional materials can be stacked. For example on top of the second layer of dielectric 105, a third layer of gate metal 145 (or 146) can be formed, which can be followed by a third layer of high-k gate 140, which can be followed by a third layer of 2D material 110 (or 111) which can be followed by a second carrier nanosheet 115, which can be followed by a fourth layer of 2D material 110 (or 111), which can be followed by a fourth layer of high-k gate 140, which can be followed by a fourth layer of gate metal 145 (or 146) on top of which a cap layer 120 can be formed.

It is understood that other 2D materials instead of 2D materials 110 or 111 can be used, and that 2D materials can be interchanged and mixed, such as for example, 2D materials 110 can be replaced with 2D material 111 at any one or more layers, and vice versa, and 2D materials 110 and 111 can be rearranged in any combination in the stack. Likewise, any gate metal 145 layer can be replaced with gate metal 146, and vice versa. The material stack can be formed based on examples reflected in FIG. 2, FIG. 17, or any other figure discussed herein.

Additional layers of 2D materials 110 or 111, nanosheets 115, gate high-k dielectric 140 and gate metal 145 could further be added on top to make the structure any N stack of transistor 100 structures tall. Any number of transistors or 2D channels 250 per transistor 100 can be contemplated and can be implemented by simply repeating the pattern as many times as needed.

Step 5410 can include isolating the structure portion of the stack. A PR mask can be used to cover the portion of the material stack in which one or more transistors 100 can be fabricated. An etch can be performed around the area that surrounds the material stack in which one or more transistors 100 are to formed. The etched out area can be filled with isolation dielectric 130, or any other dielectric suitable for this purpose. Techniques and process steps used in this method step can include, for example, techniques and fabrication steps discussed in connection with FIG. 4 or FIG. 28.

Step 5415 can include forming an electrical insulation between one or more source and drain structures (e.g., contacts) 215 and 220 and a gate structure 235. The insulation can be formed by depositing a layer of electrically insulating dielectric between the gate structure 235 and the source or drain structures 215 and 220. This can be accomplished, for example, using indent etch to remove a portion of a gate metal 145 layer from around the outer edges of the structure and deposit electrically insulating dielectric in the indent etched out regions of the gate metal 145 layer. For example, this can be implemented using techniques and steps discussed in connection with FIGS. 8-9 or FIGS. 30-36. A downward etch can be made between one or more sides of the material stack and the surrounding dielectric isolation 130, followed by an indent etch of the outer portions of the gate metal 145 layer (or alternatively gate metal 146 layer), as a result of which the layer of gate metal (145 or 146) is indent etched, leaving neighboring material layers protruding further out. This allows for cavities in the etched out portions of the gate metal 145 (or 146) which can be filled with dielectric 125 can be deposited into the etched areas to fill them with the insulator (e.g., dielectric 125). Following this step, a directional etch can be completed downward to etch out the dielectric 125 from the regions in which S/D structures 215 and 220 are to be formed.

Step 5420 can include forming the first and second source/drain 215 and 220 structures for a first transistor of the structure. In the implementations in which only a single transistor 100 is contemplated in the stack, such as for example in the example structure discussed in connection with FIGS. 1-16 or FIGS. 24-38, this may be the only step for making S/D structures 215 and 220. However, in the implementations in which two or more transistors are stacked in a single structure, such as for example in the structure discussed in connection with FIGS. 17-23 or FIGS. 39-51, this may be the first of the two or more steps to complete for the transistors 100A-N fabricated. The additional steps to be done to electrically insulate additional transistors from the first transistor of the structure can be completed using he steps discussed in connection with Step 5230.

The first and second source/drain structures 215 and 220 can serve as the source and drain contacts of a transistor 100 (or a transistor 100A of a multi-transistor structure). In some implementations, S/D structure 215 can be a source and the S/D structure 220 can be a drain of a transistor. In some implementations, S/D structure 215 can be a drain and S/D structure 220 can be the source of the transistor. S/D structures 215 and 220 can be formed using any electrically conductive material, such as S/D metal 135, or doped semiconductors or electrically conductive 2D materials. In some embodiments, a first source/drain structure 215 can formed using a material that is different than the material used in second source/drain structure 220.

S/D structures 215 and 220 can be formed for example using the techniques, such as those discussed in connection with FIG. 9-10 in which a trench on the sides of the layer stack is etched directionally downward, and in which S/D structures 215 and 220 can be formed after dielectric insulation 125 is applied to insulate the S/D structures 215 and 220 from the gate structure 235. S/D structures 215 and 220 can be formed using S/D metal 135 filling so as to create an electrical contact between the S/D metal 135 and the 2D material 110 or 111.

S/D structures 215 and 220 can be formed using techniques discussed, for example in FIG. 37, in which a GAA type gate structure 235 can be completed around 2D channels 250 and a trench can be etched for the S/D metal 135 to be deposited at the distal ends of the 2D channels 250.

Step 5425 can include forming one or more access trenches 260. Forming one or more access trenches 260 can include, for example, etching a trench via a downward selective etch of an isolation dielectric 130, leaving other layers of the material stack in-tact. Access trench 260 can be etched along the edge of a transistor structure being processed so that the access trench 260 abuts the 2D channels 250. Access trench 260 can be implemented as a trench whose cross-section is elongate and directed along the edge of the transistor 100 structure so that the access trench 260 is oriented parallel to the 2D channels 250 length being spanned between S/D structures 215 and 220).

An access trench 260 can have any length, such as the entire length of the transistor 100 structure (e.g., from S/D structure 215 to S/D structure 220, inclusively or exclusively), a portion of the length of the structure, a small or a large section of the length of the structure. Access trench 260 can be located at any point along the two sides of the structure, such as for example next to the either S/D structure 215 or 220, further away from the structure, at a mid-section of the length of the structure, or next to the ends of the structure. An access trench 260 can be formed on either side of the structure, and on both sides of the structure, abutting the length of the structure and 2D channels 250.

Access trench 260 can be used for connecting gate metal, such as gate metal 145 or gate metal 146, to the gate metal 145 (or 146) layers in the material stack. This can be done, for example, when creating a GAA type gate structure 235, which can be implemented in connection with step 5235.

Step 5430 can include completing a source and drain structures for all transistors in the stack. For example, in the implementations in which multiple transistors 100, such as transistor 100A, 100B, and any other transistors 100C-N are implemented in a single stack, electrically insulating material, such as a dielectric 155 can be inserted to insulate S/D contacts from different transistors 100. For example, once S/D metal 135 is input into the trench (such as for example using functionalities in Step 5415) an electrical insulation can be placed between S/D structures 215A and 220A of the bottom transistor 100A and S/D structures 215B and 220B of the top transistor 100B. Each transistor can have its own set of S/D structures 215 and 220 that are electrically insulated from other S/D structures 215 and 220 of other transistors 100. S/D structures 215 and 220 can be formed so that each one set of S/D structures 215 and 220 operate only with a single transistor 100.

A two transistor structure can be fabricated using steps described in connection with FIGS. 17-23 and FIGS. 39-51. Its S/D structures 215 and 220 can be isolated between different transistors. This can be implemented for example using techniques discussed in connection with FIGS. 17-19, in which S/D metal 135 is filled, followed by an etched of the portion of the filling from about mid-point of the second gate metal and upwards. A layer of dielectric 105 insulator can be inserted in the trench to the height of about mid-point of the first gate metal 146 in FIG. 19, after which the remainder of the trench can be filled with S/D metal 135. By placing the dielectric between the two pairs of gate metal layer, each one of which encloses or surrounds its own one or more 2D channels 250, S/D structures 215A and 220A of transistor 100A can be electrically insulated from S/D structures 215B and 220B of the transistor 100B.

S/D material 135 filling can be used to fill the etched out trench on the distal ends of the layer stack so as to form an electrical contact with 2D materials 110 and 111 in order to form 2D channels 250. Following the S/D metal 135 deposition, an upper portion of the S/D material 135 (e.g., the portion above the bottom transistor 100A) can be etched out down to about the mid-point of the thickness of the second gate metal 145 layer (e.g., see FIG. 19). Once this partial etch of the top portion of the S/D metal 135 is completed, an insulator dielectric 105 (or any other dielectric suitable for this electrical insulation) can be applied on top of the remaining S/D metal 135 (e.g., of the bottom transistor) so as to electrically insulate the lower S/D structures 215 and 220 from the upper S/D structures 215 and 220, to be formed. The dielectric can be filled up to the point of the third gate metal layer (counting from the substrate 101), which in FIG. 19 is the first gate metal 146 layer. Once dielectric 105 is applied, the S/D material 135 can fill the top portion of the trench (e.g., on top of the dielectric 155 layer) thereby completing the S/D structures 215 and 220 for the upper transistor.

By completing this step, S/D structures 215A and 220A of the lower transistor 100A can be electrically insulated from the S/D structures 215B and 220B of the upper transistor 100 (see FIG. 1B). At the same time, S/D structures of the lower transistor can form an electrical contact with the 2D materials around the first carrier nanosheet 115 (e.g., to form 2D channels 250 of the lower transistor), while the S/D structures of the upper transistor can form an electrical contact with the 2D materials on the second carrier nanosheet 115 (e.g., to form 2D channels 250 for the upper transistor).

Step 5435 can include completing a gate structure 235 for all transistors formed in the material layer stack. The gate structures 235 can be formed for each individual transistor, such as a transistor 100 in a single-transistor implementation, or for multi-transistor structure having transistors 100A, 100B and any other number of transistors. A gate structure 235 can include a gate high-k 140 dielectric along with a gate metal 145 or 146. The gate high-k 140 dielectric material layer can surround the 2D material 100 and/or 111 layers, thereby protecting the 2D material 100 and 111 from a short circuit that would be formed if a gate metal 145 touches them. Therefore, a gate structure 235 includes gate high-k 140 layer formed or disposed in between 2D channels 250 and gate metal 145 or 146.

Gate structure 235 can include, for example a gate-all-around (“GAA”) structure, such as the one shown and described, for example in connection with FIG. 16, 23 or 51. GAA type gate structure 235 can surround, envelop or otherwise encircle 2D channels 250 from all sides, including from the bottom, the top and the two sidewalls of the carrier nanosheets 115. The GAA type gate structures 235 may allow for passages of 2D channels 250 to and from the S/D structures 215 and 220, while encircling or surrounding 2D channels 250 from all other sides. GAA type gate structure 235 can individually surround each and every 2D channel 250 of the structure.

The gate structures 235 for different 2D channels 250 can be by design in electrical common with each other—e.g., are electrically shorted to each other. This electrical common design can be implemented when several 2D channels 250 are to be controlled simultaneously by a single gate structure 235. In some implementations, gate structures 235 of some 2D channels 250 can be electrically insulated and independent from other gate structures 235 of other 2D channels 250. This electrical common design can be done, for example, when independent operation of 2D channels 250 is contemplated.

Gate structure 235 can be implemented using steps and techniques discussed in connection with FIGS. 13-16, in which an access trench 260 can be created to enable interconnection of different layers of gate metal 145 with each other and the gate metal 145 or 146 applied through the access trench to connect all the gate metal parts into a gate structure 235. Gate structure 235 can also be formed using steps and techniques discussed in connection with FIGS. 26-27 in which high-k gate 140 dielectric is applied to cover sidewall 2D material layers 110 or 111, followed by gate metal 145 deposition.

In some implementations, independent gate structures 235 can be formed using different materials for different transistors (e.g., 100A and 100B) of a material stack. This can be done, for example, by using steps and techniques discussed in connection with FIGS. 42-45, in which the high-k gate 140 material is first applied over two different 2D channels 250. The structure is then covered by a single sheet of gate metal 145 to cover both transistors 100A and 100B in FIG. 45. The gate metal 145 can then be removed from transistor 100B structure, as discussed in connection with FIG. 49, and a different gate metal 146 can be applied to the transistor 100B, as shown in FIG. 51.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features described only in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A device comprising:
a source contact having a sidewall surface;
a drain contact having a sidewall surface;
a channel layer extending between the sidewall surfaces of the source and drain contacts, the channel layer including a 2D material; and
a gate structure isolated from the source and drain contacts by an isolation dielectric, the gate structure provided on at least one side of the channel layer, the gate structure including a gate contact and a gate dielectric between the gate contact and the 2D material, a portion of the gate dielectric positioned between the isolation dielectric and the 2D material.

2. The device of claim 1, further comprising a carrier nanosheet on which the channel layer is positioned.

3. The device of claim 2, further comprising the gate structure provided on at least a second side of the channel layer.

4. The device of claim 2, wherein the 2D material is formed between a top surface of the carrier nanosheet and the gate dielectric.

5. The device of claim 2, wherein the 2D material is formed between a bottom surface of the carrier nanosheet and the gate electric.

6. The device of claim 2, wherein the sidewall surface of the source contact and sidewall surface of the drain contact extend orthogonal to and underlying substrate.

7. The device of claim 6, wherein the carrier nanosheet is oriented parallel with the substrate.

8. The device of claim 1, further comprising the source contact electrically connected to a first end of the channel layer and the drain contact electrically connected to a second end of the channel layer.

9. The device of claim 1, wherein the source contact includes a first electrically conductive material and the drain contact includes a second electrically conductive material that is different than the first electrically conductive material.

10. A method comprising:
forming a patterned stack of layers including:
a channel layer including a 2D material; and
a gate structure formed on at least one side of the 2D material, the gate structure including a gate contact and a gate dielectric between the gate contact and the 2D material;
forming an isolation dielectric adjacent the gate structure; and
forming source and drain contacts on respective sides of the channel, the source and drain contacts being isolated from the gate contact by the isolation dielectric, the channel layer extending between the source and drain contacts.

11. The method of claim 10, further comprising forming the channel layer supported by a carrier nanosheet.

12. The method of claim 11, further comprising forming the gate structure on at least a second side of the channel layer.

13. The method of claim 11, further comprising forming the 2D material between a top surface of the carrier nanosheet and the gate dielectric.

14. The method of claim 11, further comprising forming the 2D material between a bottom surface of the carrier nanosheet and the gate electric.

15. The method of claim 11, further comprising forming the source contact and the drain contact to each be extended orthogonal to an underlying substrate.

16. The method of claim 15, further comprising forming the carrier nanosheet to be oriented parallel with the substrate.

17. The method of claim 10, further comprising forming the source contact to be electrically connected to a first end of the channel layer and the drain contact to be electrically connected to a second end of the channel layer.

18. The method of claim 10, further comprising forming the source contact with a first electrically conductive material and the drain contact with a second electrically conductive material that is different than the first electrically conductive material.

19. A transistor, comprising:
a first 2D material channel supported by a first carrier nanosheet extending between a source structure and a drain structure;
a second 2D material channel supported by a second carrier nanosheet extending between the source structure and the drain structure and above the first carrier nanosheet; and
a gate structure including a gate metal and a high-k gate material formed between the first 2D material channel and the gate metal and between the second 2D material channel and the gate metal.

20. The transistor of claim 1, wherein the gate metal at least partially surrounds the first 2D material channel and is common with the gate metal at least partially surrounding the second 2D material channel.
